(19) United States
(12) Patent Application Publication
(10) Pub. No.: US 2026/0129972 A1
(43) Pub. Date: May 7, 2026

(54) DISPLAY PANEL AND ELECTRONIC DEVICE INCLUDING THE SAME

(71) Applicant: Samsung Display Co., Ltd., Yongin-si (KR)

(72) Inventors: Sewan SON, Yongin-si (KR); Hyunil KANG, Yongin-si (KR); Kyunghae PARK, Yongin-si (KR); Kihwan SEOK, Yongin-si (KR); Jinsung AN, Yongin-si (KR); Minwoo WOO, Yongin-si (KR); Seunghyun LEE, Yongin-si (KR); Wangwoo LEE, Yongin-si (KR); Jiseon LEE, Yongin-si (KR); Hyeri CHO, Yongin-si (KR)

(73) Assignee: Samsung Display Co., Ltd., Yongin-si (KR)

(21) Appl. No.: 19/370,059

(22) Filed: Oct. 27, 2025

(30) Foreign Application Priority Data
Oct. 25, 2024 (KR) 10-2024-0147866

(51) Int. Cl. H10D 86/40; H10D 86/60; H10H 29/32

(52) U.S. Cl. CPC H10D 86/411; H10D 86/423; H10D 86/60; H10H 29/32

(57) ABSTRACT

A display panel and an electronic device are provided. The display panel includes a substrate, an unevenness layer on the substrate, and a transistor including a gate electrode and a semiconductor layer on the unevenness layer. At least one of a surface of the unevenness layer or a surface of the semiconductor layer includes unevenness.

### CROSS-REFERENCE TO RELATED APPLICATION

This application is based on and claims priority under 35 U.S.C. § 119 to Korean Patent Application No. 10-2024-0147866, filed on Oct. 25, 2024, in the Korean Intellectual Property Office, the disclosure of which is incorporated by reference herein in its entirety.

### BACKGROUND

### 1. Field

One or more embodiments relate to an electronic device, and more particularly, to a display panel included in the electronic device.

### 2. Description of the Related Art

Mobility-based electronic devices have been widely used. In addition to compact electronic devices such as mobile phones, tablet personal computers (PCs) have recently become widely used as portable electronic devices.

Such a mobile electronic device includes a display panel to provide a user with visual information, such as images or videos, and to support various functions. Recently, as other components for driving display panels have become smaller, the proportion of display panels in electronic devices has been gradually increasing. Additionally, bendable structures have been developed that allow a flat-panel display to be bent to a certain angle.

### SUMMARY

According to an aspect of the disclosure, a display panel includes a substrate, an unevenness layer on the substrate, and a transistor including a gate electrode and a semiconductor layer on the unevenness layer, wherein at least one of a surface of the unevenness layer or a surface of the semiconductor layer includes unevenness.

According to another aspect of the disclosure, an electronic device may include the display panel and a lower cover forming an outer appearance of the display panel and having an opening exposing a portion of the display panel.

According to another aspect of the disclosure, an electronic device may include: a display panel including a light-emitting diode; a field-effect transistor configured to drive the light-emitting diode and including a source electrode, a drain electrode, and a gate electrode; a polysilicon layer below the source electrode, the drain electrode, and the gate electrode, and directly connected to the source electrode; an oxide semiconductor layer between the source electrode and the polysilicon layer, and contacting the source electrode and the polysilicon layer; and a processor configured to control the display panel to display an image, wherein at least one of a surface of the polysilicon layer or a surface of the oxide semiconductor layer includes unevenness.

### BRIEF DESCRIPTION OF DRAWINGS

The above and other aspects of the disclosure will be more apparent from the following description taken in conjunction with the accompanying drawings, in which:

FIG. 1 is a perspective view schematically illustrating an electronic device according to one or more embodiments;

FIG. 2 is an exploded perspective view of the electronic device of FIG. 1;

FIG. 3 is a block diagram schematically illustrating the electronic device of FIG. 1;

FIG. 4 is a plan view schematically illustrating a display panel according to one or more embodiments;

FIG. 5 is a side view schematically illustrating the display panel of FIG. 4;

FIG. 6 is a plan view schematically illustrating the display panel of FIG. 4;

FIG. 7 is an equivalent circuit diagram of a pixel in a display area of the display panel of FIG. 6;

FIG. 8 is a layout diagram schematically showing positions of transistors, capacitors, and the like in pixels in a display area of the display panel of FIG. 6;

FIG. 9 is a layout diagram schematically showing positions of a first transistor, a second connection electrode, and an unevenness area in the pixels in the display area of the display panel of FIG. 8;

FIG. 10 is a cross-sectional view schematically illustrating a cross-section taken along line B-B′ of FIG. 6;

FIG. 11 is an enlarged cross-sectional view illustrating region F of FIG. 10;

FIG. 12A is a cross-sectional view schematically illustrating a portion of a display area of a display panel, according to one or more embodiments;

FIG. 12B is a cross-sectional view schematically illustrating a portion of a display area of a display panel, according to one or more embodiments;

FIG. 13A is a cross-sectional view schematically illustrating a portion of a display area of a display panel, according to one or more embodiments;

FIG. 13B is a cross-sectional view schematically illustrating a portion of a display area of a display panel, according to one or more embodiments;

FIG. 14A is a cross-sectional view schematically illustrating a portion of a display area of a display panel, according to one or more embodiments;

FIG. 14B is a cross-sectional view schematically illustrating a portion of a display area of a display panel, according to one or more embodiments;

FIG. 15A is a cross-sectional view schematically illustrating a portion of a display area of a display panel, according to one or more embodiments;

FIG. 15B is a cross-sectional view schematically illustrating a portion of a display area of a display panel, according to one or more embodiments;

FIG. 16A is a cross-sectional view schematically illustrating a portion of a display area of a display panel, according to one or more embodiments;

FIG. 16B is a cross-sectional view schematically illustrating a portion of a display area of a display panel, according to one or more embodiments;

FIG. 17 is a cross-sectional view schematically illustrating a portion of a display area of a display panel, according to one or more embodiments;

FIG. 18A is a cross-sectional view schematically illustrating a portion of a display area of a display panel, according to one or more embodiments;

FIG. 18B is a cross-sectional view schematically illustrating a portion of a display area of a display panel, according to one or more embodiments;

FIG. 19A is a cross-sectional view schematically illustrating a portion of a display area of a display panel, according to one or more embodiments;

FIG. 19B is a cross-sectional view schematically illustrating a portion of a display area of a display panel, according to one or more embodiments;

FIG. 20 is a plan view schematically illustrating an unevenness layer arranged in a display area of a display panel, according to one or more embodiments;

FIGS. 21 to 28 are cross-sectional views schematically illustrating a portion of a display area of a display panel, according to one or more embodiments;

FIG. 29 is a block diagram of an electronic device according to one or more embodiments; and

FIGS. 30 to 32 are schematic views of electronic devices according to various embodiments.

### DETAILED DESCRIPTION

Example embodiments are described in greater detail below with reference to the accompanying drawings.

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The effects and features of the disclosure, and ways to achieve them will become apparent by referring to embodiments that will be described later in detail with reference to the drawings. However, the disclosure is not limited to the following embodiments but may be embodied in various forms.

It will be understood that although the terms “first,” “second,” etc. may be used herein to describe various elements, these elements should not be limited by these terms. These terms are only used to distinguish one element from another.

Singular expressions, unless defined otherwise in contexts, include plural expressions.

In the embodiments below, it will be further understood that the terms “comprise” and/or “have” used herein specify the presence of stated features or elements, but do not preclude the presence or addition of one or more other features or elements.

In the embodiments below, it will be understood when a portion such as a layer, an area, or an element is referred to as being “on” or “above” another portion, it may be directly on or above the other portion, or an intervening portion may also be present.

In the embodiments below, an x-axis, a y-axis, and a z-axis are not limited to three axes on a rectangular coordinates system but may be construed as including these axes. For example, an-x axis, a y-axis, and a z-axis may be at right angles or may also indicate different directions from one another, which are not at right angles.

In the present disclosure, overlapping in plan view may refer to overlapping in a third direction (i.e., a z-direction).

When an embodiment is implementable in another manner, a predetermined process order may be different from a described one. For example, two processes that are consecutively described may be substantially simultaneously performed or may be performed in an opposite order to the described order.

When a display panel incorporating an oxide semiconductor layer is in operation, current flows through the oxide semiconductor layer in response to changes in the applied voltage. Due to the high sensitivity of the oxide semiconductor layer to voltage and current variations, precise control of the display panel can be challenging, as even a small voltage change in a specific area may cause a rapid current fluctuation. One or more embodiments of the present disclosure provide a display panel with a structure and materials that enable precise control of its operation.

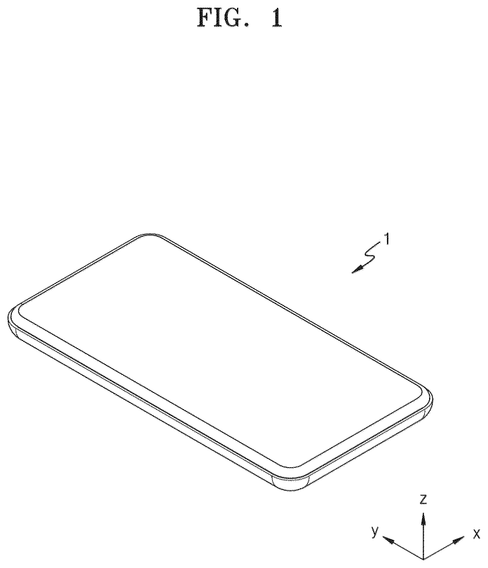

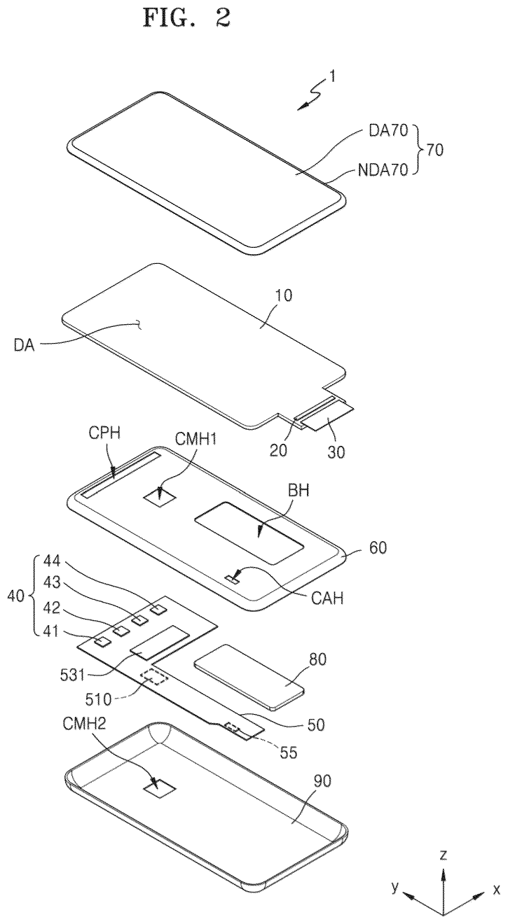

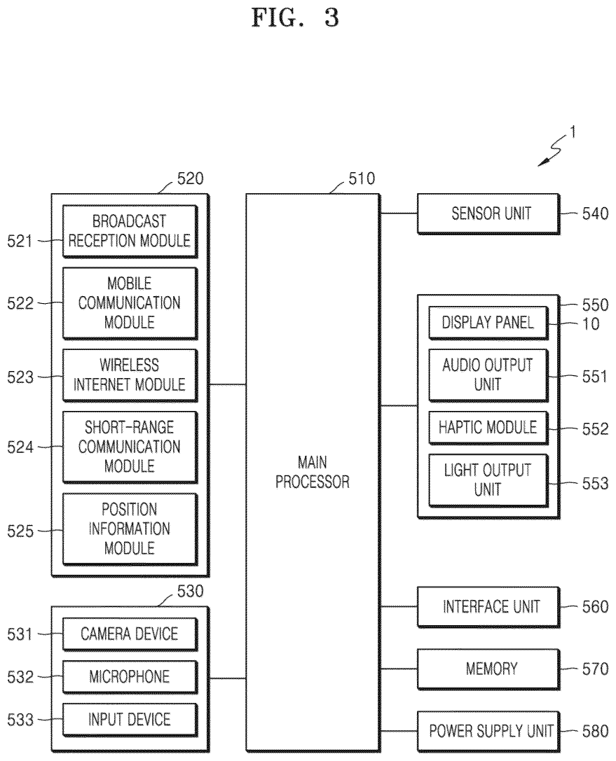

FIG. 1 is a perspective view schematically illustrating an electronic device 1 according to one or more embodiments, FIG. 2 is an exploded perspective view schematically illustrating the electronic device 1 of FIG. 1, and FIG. 3 is a block diagram schematically illustrating the electronic device 1 of FIG. 1.

Referring to FIGS. 1 to 3, the electronic device 1 according to one or more embodiments may include a device, that displays moving images or still images, and may be one of various products such as a mobile phone, smart phone, tablet personal computers (PC), mobile communication terminal, electronic notebook, e-book, portable multimedia player (PMPs), a navigation device, and ultra-mobile PC (UMPC), as well as a television, laptop computer, monitor, billboard, or the Internet of Things (IoT) device. Alternatively, the electronic device 1 according to one or more embodiments may include a wearable device such as a smart watch, a watch phone, a glasses-type display, or a head mounted display (HMD). Alternatively, the electronic device 1 according to one or more embodiments may include a dashboard of a vehicle, a center information display (CID) arranged on a center fascia or dashboard of a vehicle, a room mirror display replacing a side mirror of a vehicle, or a display arranged on the back of a front seat as entertainment for the rear seats of a vehicle.

In FIGS. 1 and 2, for convenience of description, the electronic device 1 according to one or more embodiments is illustrated as a smart phone. The electronic device 1 may include a cover window 70, a display panel 10, a data driver 20, a display circuit board 30, components 40, a bracket 60, a main circuit board 50, a battery 80, and/or a lower cover 90.

In a plan view of the present specification, “left”, “right”, “up”, and “down” indicate a direction when viewing the display panel 10 from a vertical direction of the display panel 10. For example, “left” indicates a −x direction, “right” indicates a +x direction, “up” indicates a +y direction, and “down” indicates a −y direction.

The electronic device 1 may be viewed to have an approximately rectangular shape in a plan view. For example, the electronic device 1 may be shown as having an approximately rectangular shape having a short side in an x-axis direction and a long side in a y-axis direction in an xy-plane, as illustrated in FIG. 1. A corner where the short side in the x-axis direction and the long side in the y-axis direction meet each other may form a right angle or may have a round shape with a certain curvature. In a plan view, the electronic device 1 may also have a polygonal shape other than a rectangular shape or may have an elliptical shape, an irregular shape, etc.

The cover window 70 may be arranged on the display panel 10 to at least partially cover an upper surface of the display panel 10. The cover window 70 may protect the upper surface of the display panel 10.

The cover window 70 may include a transparent cover portion DA70 corresponding to the display panel 10 and a light-blocking cover portion NDA70 surrounding the transparent cover portion DA70. The light-blocking cover portion NDA70 may include an opaque material (e.g., a colored opaque material) that blocks light. The light-blocking cover portion NDA70 may include a pattern that may be displayed to a user when not displaying an image.

The display panel 10 may be arranged under the cover window 70. The display panel 10 may overlap the transparent cover portion DA70 of the cover window 70. The display panel 10 includes a display area DA. The display area DA is an area where an image is displayed, and the display area DA may include an area (hereinafter, component area) configured to transmit light emitted from the components 40 positioned below the display panel 10. Components may include sensors, cameras, or other sensors that utilize visible light, infrared, or sound.

The display panel 10 may be a light-emitting display panel including a light-emitting diode. The light-emitting diode may be an organic light-emitting diode (OLED) including an organic emission layer, or an inorganic light-emitting diode including an inorganic material. An inorganic light-emitting diode may include a PN junction diode including inorganic semiconductor-based materials. When a voltage is applied to the PN junction diode in a forward direction, holes and electrons are injected thereto, and energy generated by recombination of the holes and electrons is converted into light energy to emit light of a certain color. The inorganic light-emitting diode may have a width from several micrometers to hundreds of micrometers. The inorganic light-emitting diode may be referred to as a micro-light emitting diode (micro-LED).

The display panel 10 may be a rigid display panel that is not bent easily, or a flexible display panel that may be easily bent, folded, or rolled. For example, the display panel 10 may be a foldable display panel that may be folded and unfolded, a curved display panel with a curved display surface, a bent display panel with a bent area other than the display surface, a rollable display panel that may be rolled and unfolded, or a stretchable display panel that may be stretched.

The display panel 10 may be transparent, allowing objects or backgrounds arranged on a lower surface of the display panel 10 to be viewed from the upper surface of the display panel 10. Alternatively, the display panel 10 may be a reflective display panel, capable of reflecting an object or background on the upper surface of the display panel 10.

The data driver 20 may be mounted on the display panel 10 in the form of an integrated circuit (IC). The disclosure is not limited thereto, and for example, the data driver 20 may be mounted on the display circuit board 30.

The display circuit board 30 may be attached to one side of the display panel 10. The display circuit board 30 may be a flexible printed circuit board (FPCB) that may be bent, a rigid printed circuit board (PCB) that is hard and does not bend easily, or a composite printed circuit board including both a rigid printed circuit board and a flexible printed circuit board. A touch sensor driver may be mounted on the display circuit board 30. The touch sensor driver may be formed using an integrated circuit. The touch sensor driver may be electrically connected to touch electrodes of a touch screen layer of the display panel 10 through the display circuit board 30.

The touch screen layer of the display panel 10 may detect a user's touch input by using at least one of several touch methods, such as a resistive film method or an electrostatic capacitance method. When the touch screen layer of the display panel 10 detects a user's touch input by using an electrostatic capacitance method, the touch sensor driver may apply driving signals to driving electrodes among the touch electrodes, and detect voltages charged in mutual capacitances (hereinafter referred to as “mutual capacitance”) between the driving electrodes and the sensing electrodes through the sensing electrodes among the touch electrodes, thereby determining whether the user has touched.

A user's touch may include a contact touch and a proximity touch. Contact touch indicates that a user's finger or an object such as a pen directly contacts the cover window 70 arranged on the touch screen layer. Proximity touch indicates that an object such as a user's finger or pen is positioned close to the cover window 70, such as hovering. The touch sensor driver may transmit sensor data to a main processor 510 according to detected voltages, and the main processor 510 may calculate touch coordinates where a touch input occurred, by analyzing the sensor data.

A controller for supplying driving voltages for driving pixels, gate drivers and/or the data driver 20 of the display panel 10 may be arranged on the display circuit board 30.

The bracket 60 for supporting the display panel 10 may be arranged below the display panel 10. The bracket 60 may include plastic, metal, or both plastic and metal. The bracket 60 may include a first camera hole CMH1 into which a camera device 531 is inserted, a battery hole BH in which the battery 80 is arranged, a cable hole CAH through which a cable connected to the display circuit board 30 passes, and a component hole CPH corresponding to the components 40. The component hole CPH may overlap the components 40 of the main circuit board 50 in plan view, when viewed from a third direction (i.e., a z-axis direction). For reference, the display area DA of the display panel 10 may overlap the components 40 of the main circuit board 50 in plan view. Depending on the need, the bracket 60 may not have the component hole CPH.

The components 40 included in the electronic device 1 may include a first component 41, a second component 42, a third component 43, and a fourth component 44 overlapping the display panel 10. Each of the first component 41, the second component 42, the third component 43, and the fourth component 44 may include at least one of a proximity sensor, an illumination sensor, an iris sensor, a facial recognition sensor, and a camera (or image sensor). A proximity sensor using infrared rays may detect an object positioned close to the upper surface of the electronic device 1, and an illumination sensor may detect the brightness of light incident on the upper surface of the electronic device 1. Additionally, the iris sensor may capture an image of an iris of a person positioned on the upper surface of the electronic device 1, and the camera may obtain image data for an object positioned on the upper surface of the electronic device 1. The components 40 are not limited to a proximity sensor, an illumination sensor, an iris sensor, a facial recognition sensor, and/or a camera, and may include other sensors.

The main circuit board 50 and the battery 80 may be arranged below the bracket 60. The main circuit board 50 may be a printed circuit board or a flexible printed circuit board.

The main circuit board 50 may include the main processor 510, the camera device 531, a main connector 55, and the components 40. The main processor 510 may be formed using an integrated circuit. Depending on the need, the electronic device 1 may include the camera device 531 positioned on an upper surface of the main circuit board 50, as well as a camera device positioned on a lower surface of the main circuit board 50. Each of the main processor 510 and the main connector 55 may be arranged on either the upper surface or the lower surface of the main circuit board 50. The main circuit board 50 may be electrically connected to the display circuit board 30 through the main connector 55, for example.

The main processor 510 may control all functions of the electronic device 1. For example, the main processor 510 may output digital video data to the data driver 20 via the display circuit board 30 so that the display panel 10 displays an image. The main processor 510 may receive detection data from the touch sensor driver. The main processor 510 may determine whether the user has touched, based on the detection data and execute an action corresponding to a user's direct touch or proximity touch. The main processor 510 may include an application processor, a central processing unit, or a system chip including an integrated circuit.

The camera device 531 processes image frames, such as still images or moving images, obtained by an image sensor in camera mode and outputs the same to the main processor 510. The camera device 531 may include at least one of a camera sensor (e.g., charge coupled device (CCD) or complementary metal oxide semiconductor (CMOS)), a photo sensor (or image sensor), and a laser sensor.

A cable passing through the cable hole CAH of the bracket 60 may be connected to the main connector 55, and the main circuit board 50 may be electrically connected to the display circuit board 30 through the cable.

The electronic device 1 may be represented by a block diagram as illustrated in FIG. 3. The electronic device 1 may include, in addition to the main processor 510, a wireless communication unit 520, an input unit 530, a sensor unit 540, an output unit 550, an interface unit 560, a memory 570, and/or a power supply unit 580, as illustrated in FIG. 3.

The wireless communication unit 520 may include at least one of a broadcast reception module 521, a mobile communication module 522, a wireless Internet module 523, a short-range communication module 524, and a position information module 525.

The broadcast reception module 521 receives broadcast signals and/or broadcast-related information from an external broadcast management server through a broadcast channel. Broadcast channels may include satellite channels or terrestrial channels.

The mobile communication module 522 transmits and receives a wireless signal with at least one of a base station, an external terminal, and a server on a mobile communication network constructed according to technical standards or communication methods for mobile communication (e.g., GSM (Global System for Mobile communication (GSM), CDMA (Code Division Multi Access (CDMA), Code Division Multi Access 2000(CDMA 2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), etc.). Wireless signals may include various forms of data, such as voice call signals, video call signals, or text/multimedia message transmission and reception.

The wireless Internet module 523 refers to a module for wireless Internet access. The wireless Internet module 523 may be configured to transmit and receive wireless signals in a communication network according to wireless Internet technologies. The wireless Internet technology may be, for example, wireless LAN (WLAN), Wireless-Fidelity (Wi-Fi), Wi-Fi Direct, and/or Digital Living Network Alliance (DLNA).

The short-range communication module 524 is for short-range communication and may support short-range communication using at least one of Bluetooth™, Radio Frequency Identification (RFID), Infrared Data Association (IrDA), Ultra Wideband (UWB), ZigBee, Near Field Communication (NFC), Wi-Fi, Wi-Fi Direct, and Wireless USB (Wireless Universal Serial Bus) technologies. The short-range communication module 524 may support, via a short-range wireless communication network, wireless communication between the electronic device 1 and a wireless communication system, between the electronic device 1 and another electronic device, or between the electronic device 1 and a network where another electronic device (or an external server) is located. The short-range wireless network may be a Wireless Personal Area Network. The other electronic device may be a wearable device capable of exchanging (or linking with) data with the electronic device 1.

The position information module 525 may obtain position information of the electronic device 1 and may include a Global Positioning System (GPS) module or a Wi-Fi module.

The input unit 530 may include an image input unit such as the camera device 531 for inputting an image signal, an audio input unit such as a microphone 532 for inputting an audio signal, and an input device 533 for receiving information from a user. The camera device 531 processes image frames, such as still images or moving images, obtained by an image sensor in video call mode or photographing mode. The processed image frame may be displayed on the display panel 10 or stored in the memory 570. The microphone 532 processes external acoustic signals into electrical voice data. The processed voice data may be utilized in various manners depending on a function being performed (or an application being executed) in the electronic device 1.

The main processor 510 may control the operation of the electronic device 1 based on an input received through the input device 533. The input device 533 may include a mechanical input means or a touch input means such as a button, a dome switch, a jog wheel, a jog switch, etc. located on a rear surface or a side surface of the electronic device 1. The touch input means may include a touch screen layer of the display panel 10.

The sensor unit 540 may include one or more sensors that sense at least one of information within the electronic device 1, information about the surrounding environment surrounding the electronic device 1, and user information, and generate a sensing signal corresponding thereto. The main processor 510 may control driving or operation of the electronic device 1 based on these sensing signals, or perform data processing, functions, or operations related to an application installed in the electronic device 1. The sensor unit 540 may be a proximity sensor, an illumination sensor, or a facial recognition sensor as described above with respect to the components 40. The sensor unit 540 may include an acceleration sensor, a magnetic sensor, a G-sensor, a gyroscope sensor, a motion sensor, an RGB sensor, an infrared (IR) sensor, a finger scan sensor, an ultrasonic sensor, an optical sensor, and/or a battery gauge. In addition, the sensor unit 540 may include an environmental sensor or a chemical sensor. The environmental sensor may include, for example, a barometer, a hygrometer, a thermometer, a radiation detection sensor, a heat detection sensor, and/or a gas detection sensor. The chemical sensor may include, for example, electronic noses, healthcare sensors and/or biometric sensors.

The output unit 550 may output information related to vision, hearing, or tactile sensations, and may include at least one of the display panel 10, an audio output unit 551, a haptic module 552, and a light output unit 553.

The display panel 10 displays (outputs) information processed in the electronic device 1. For example, the display panel 10 may display execution screen information of an application running on the electronic device 1, display a user interface (UI) according to the execution screen information, or display graphic user interface (GUI) information. The display panel 10 may include a display layer that displays an image and a touch screen layer that detects a user's touch input. Thus, the display panel 10 may function as one of the input devices 533 that provides an input interface between the electronic device 1 and the user, and at the same time, may function as one of the output units 550 that provides an output interface between the electronic device 1 and the user.

The audio output unit 551 may output audio data received from the wireless communication unit 520 or stored in the memory 570 in a call signal reception mode, a call mode, a recording mode, a voice recognition mode, and/or a broadcast reception mode. The audio output unit 551 may also output an audio signal related to a function performed in the electronic device 1 (e.g., a call signal reception sound, a message reception sound, etc.). The audio output unit 551 may include a receiver and a speaker. At least one of the receiver and the speaker may be a sound generating device attached to a lower portion of the display panel 10 to vibrate the display panel 10 and output sound. The sound generating device may include a piezoelectric element or piezoelectric actuator, which contracts and expands in response to an electric signal, or an exciter that generates magnetic force by using a voice coil to vibrate the display panel 10.

The haptic module 552 generates various tactile effects that a user can feel. The haptic module 552 may provide vibration to a user as a tactile effect. The haptic module 552 may not only deliver a tactile effect through direct contact, but may also be implemented so that a user can feel the tactile effect through the muscle sense of the fingers or arms, etc.

The light output unit 553 outputs a signal to notify the occurrence of an event by using light from a light source. Examples of events occurring in the electronic device 1 may include receiving a message, receiving a call signal, receiving a missed call, an alarm, a schedule reminder, receiving an email, and/or receiving information through an application. A signal output from the light output unit 553 is implemented as the electronic device 1 emits light of a single color or multiple colors through a front surface or a rear surface thereof. The signal output may be terminated when the electronic device 1 detects the user's acknowledgement of the event.

The interface unit 560 serves as a passageway for various types of external devices connected to the electronic device 1. The interface unit 560 may include at least one of a wired/wireless headset port, an external charger port, a wired/wireless data port, a memory card port, a port for connecting a device equipped with an identification module, an audio input/output (I/O) port, a video I/O port, and an earphone port. When an external device is connected to the interface unit 560, the electronic device 1 may perform appropriate control related to the connected external device.

The memory 570 stores data that supports various functions of the electronic device 1. The memory 570 may store a plurality of applications (application programs) running on the electronic device 1, data for the operation of the electronic device 1, and/or commands. At least some of the plurality of applications may be downloaded from an external server via wireless communication. The memory 570 may store applications for the operation of the main processor 510 and also temporarily store input/output data, such as a phone book, messages, still images, and/or moving images. Additionally, the memory 570 may store haptic data for various patterns of vibration provided to the haptic module 552 and audio data regarding various sounds provided to the audio output unit 551.

The memory 570 may include at least one type of storage medium among a flash memory type, a hard disk type, a solid state disk type (SSD), a silicon disk drive type (SDD), a multimedia card micro type, a card type memory (for example, an SD or XD memory, etc.), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk.

The power supply unit 580 receives external power and/or internal power under the control of the main processor 510 and supplies power to each component included in the electronic device 1. The power supply unit 580 may include the battery 80. Additionally, the power supply unit 580 may include a connection port, which may be an example of the interface unit 560 to which an external charger that supplies power for charging the battery is electrically connected. Alternatively, the power supply unit 580 may allow the battery 80 to be charged wirelessly. The battery 80 may be positioned so as not to overlap the main circuit board 50 in plan view. The battery 80 may overlap the battery hole BH of the bracket 60.

The lower cover 90 forms the exterior of the electronic device 1 and may have an opening that exposes a portion of the display panel 10. The lower cover 90 has an open shape corresponding to the display panel 10 and may be fastened to the display panel 10. The lower cover 90 may be positioned on the opposite side to the cover window 70 with the display panel 10 therebetween. The lower cover 90 may be arranged under the main circuit board 50 and the battery 80. The lower cover 90 may be and fastened and fixed to the bracket 60. The lower cover 90 may form the exterior of a lower surface of the electronic device 1. The lower cover 90 may include plastic, metal, or both plastic and metal.

A second camera hole CMH2 that exposes a lower surface of the camera device 531 may be formed in the lower cover 90. The position of the camera device 531 and the positions of the first camera hole CMH1 and the second camera hole CMH2 corresponding to the camera device 531 are not limited to those illustrated in FIG. 2 and may be changed in various manners.

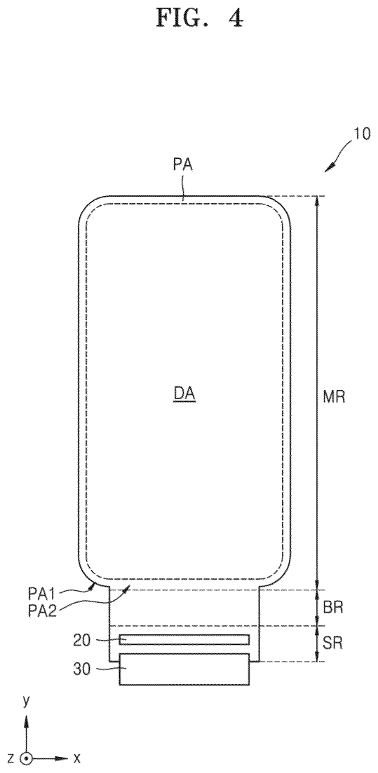

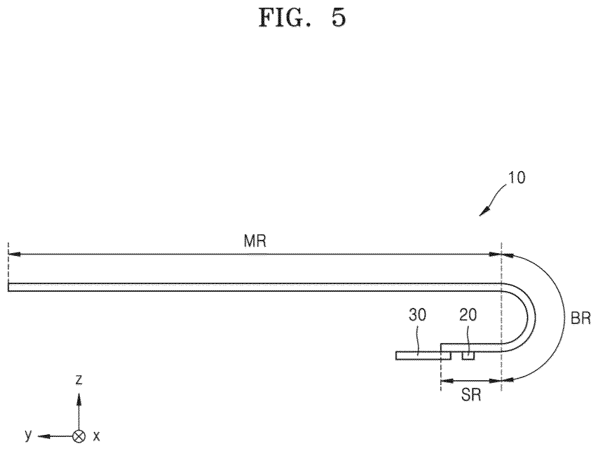

FIG. 4 is a plan view schematically illustrating the display panel 10 according to one or more embodiments, and FIG. 5 is a side view schematically illustrating the display panel of FIG. 4. The electronic device 1 described above may include the display panel 10 as that illustrated in FIGS. 4 and 5.

The display panel 10 may include the display area DA and a peripheral area PA outside the display area DA. The display area DA is a portion that displays an image, and a plurality of pixels may be arranged therein. The display area DA may have various shapes, such as a circle, an ellipse, a polygon, or a shape of a specific shape. In FIG. 4, the display area DA having a roughly rectangular shape with rounded corners is illustrated.

The peripheral area pa may be located outside the display area DA. The peripheral area PA may include a first peripheral area PA1 arranged to surround at least a portion of the display area DA and a second peripheral area PA2 positioned at the bottom of the display area DA and extending in the first direction (x-axis direction). A width of the second peripheral area PA2 in the first direction (x-axis direction) may be less than a width of the display area DA. The structure allows at least a portion of the second peripheral area PA2 to be easily bent.

The shape of a plane of the display panel 10 illustrated in FIG. 4 may be substantially the same as the shape of a substrate 100 included in the display panel 10. When the display panel 10 includes the display area DA and the peripheral area PA outside the display area DA, it may be regarded that the substrate 100 includes the display area DA and the peripheral area PA outside the display area DA. Hereinafter, for convenience, the substrate 100 having the display area DA and the peripheral area PA is described.

The display panel 10 may include a main region MR, a bending region BR outside the main region MR, and a sub-region SR spaced apart from the main region MR with the bending region BR therebetween. The main region MR may be arranged on one side of the bending region BR, and the sub-region SR may be arranged on the other side of the bending region BR. The display panel 10 may be bent in the bending region BR as illustrated in FIG. 5, and at least a portion of the sub-region SR may overlap the main region MR in plan view. FIG. 5 illustrates that the display panel 10 is bent, but the disclosure is not limited thereto. For example, the display panel 10 may be a foldable display panel, in which case the display panel 10 may be bent within the display area DA about a bending axis crossing the display area DA. If necessary, the display panel 10 may not be bent. The sub-region SR may be a non-displayed area.

The data driver 20 may be arranged in the sub-region SR of the display panel 10. The data driver 20 may be arranged on the display panel 10 in the form of an integrated circuit (IC). For example, the data driver 20 may be a data driving integrated circuit that generates a data signal.

The display circuit board 30 may be attached to the end of the sub-region SR of the display panel 10. The display circuit board 30 may be electrically connected to the data driver 20 or the like through a pad of the sub-region SR of the display panel 10.

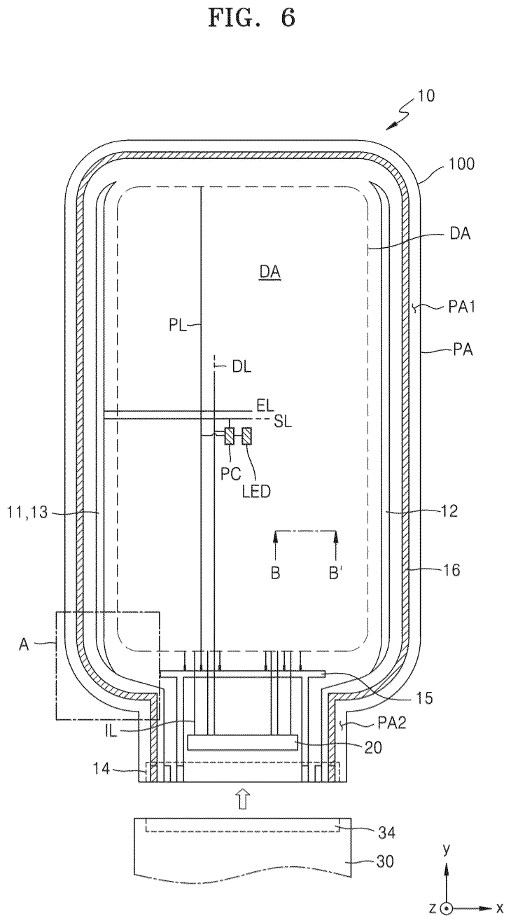

FIG. 6 is a plan view schematically illustrating the display panel 10 of FIG. 4. As illustrated in FIG. 6, the display panel 10 may include the substrate 100. Various components forming the display panel 10 may be arranged on the substrate 100.

The substrate 100 may include glass, ceramic, metal, or polymer resin. The substrate 100 may include a polymer resin, for example, polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including two layers including the polymer resin and an inorganic layer between the layers. Alternatively, the substrate 100 may have a structure in which layers including the polymer resin and inorganic layers are alternately stacked. The inorganic layer may include, for example, silicon oxide, silicon nitride or silicon oxynitride.

Pixels are arranged in the display area DA, and the display area DA may provide an image using light emitted from the pixels. Each pixel may include a light-emitting diode LED, which may be electrically connected to a pixel circuit PC. The pixel circuit PC and the light-emitting diode LED may be arranged in the display area DA. In FIG. 6, for convenience, the pixel circuit PC and the light-emitting diode LED positioned side by side are illustrated, but the pixel circuit PC and the light-emitting diode LED may overlap at least partially. For example, the light-emitting diode LED may be arranged on the pixel circuit PC.

A gate driving circuit, a pad 14, a first power supply line 15, and a second power supply line 16 may be arranged in the peripheral area PA. The gate driving circuit may include, for example, a first scan driving circuit 11, a second scan driving circuit 12, and/or a light emission control driving circuit 13.

The first scan driving circuit 11 may provide a scan signal to the pixel circuit PC through a gate line SL. The second scan driving circuit 12 may be arranged on the opposite side of the first scan driving circuit 11 with the display area DA therebetween. Some of the pixel circuits PC arranged in the display area DA may be electrically connected to the first scan driving circuit 11, and the other pixel circuits may be connected to the second scan driving circuit 12. In some cases, the second scan driving circuit 12 may be omitted.

The light emission control driving circuit 13 may be arranged on one side of the display area DA, similar to the first scan driving circuit 11. The light emission control driving circuit 13 may provide a light emission control signal to the pixel P through a light emission control line EL. In FIG. 6, the light emission control driving circuit 13 is illustrated as being arranged only on one side of the display area DA, but the disclosure is not limited thereto. For example, the display panel 10 may include light emission control driving circuits 13 arranged on one side and the other side of the display area DA. Alternatively, the first scan driving circuit 11 may be arranged on one side of the display area DA, and the light emission control driving circuit 13 may be arranged on the other side thereof.

The pad 14 may be arranged in the second peripheral area PA2 of the substrate 100. The pad 14 may be exposed and not covered by an insulating layer and electrically connected to the display circuit board 30. A pad 34 of the display circuit board 30 may be electrically connected to the pad 14 of the display panel 10.

The display circuit board 30 may be configured to transmit signals or power from the controller to the display panel 10. A control signal generated in the controller may be transmitted to each gate driving circuit through the display circuit board 30. Additionally, the controller may provide a first power voltage ELVDD and a second power voltage ELVSS to the first power supply line 15 and the second power supply line 16. The first power voltage ELVDD (hereinafter referred to as driving voltage) may be provided to each pixel circuit PC through a driving voltage line PL connected to the first power supply line 15, and the second power voltage ELVSS (hereinafter referred to as common voltage) may be provided to a common electrode of the light-emitting diode LED connected to the second power supply line 16. The first power supply line 15 may extend in the first direction (x-axis direction). The second power supply line 16 may have a loop shape with one side open and thus partially surround the display area DA.

A data signal of the data driver 20 may be transmitted to the pixel circuit PC through a data line DL electrically connected to an input line IL via the input line IL.

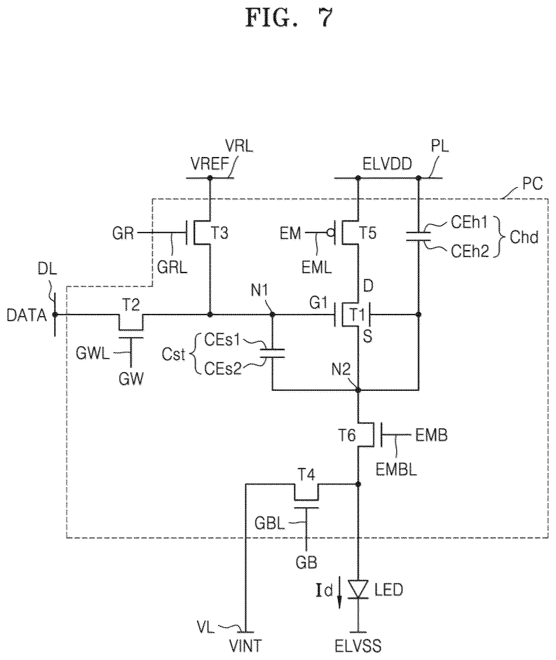

FIG. 7 is an equivalent circuit diagram of one pixel arranged in the display area DA of the display panel 10 of FIG. 6. As illustrated in FIG. 7, the pixel circuit PC connected to the light-emitting diode LED may include a plurality of transistors and a plurality of capacitors. For example, the pixel circuit PC may include a first transistor T1, a second transistor T2, a third transistor T3, a fourth transistor T4, a fifth transistor T5, a sixth transistor T6, a storage capacitor Cst, and a hold capacitor Chd.

The first transistor T1 may be a driving transistor configured to output a driving current corresponding to a data signal DATA, and the second transistor T2, the third transistor T3, the fourth transistor T4, the fifth transistor T5, and the sixth transistor T6 may be switching transistors configured to transmit signals through on/off. A first terminal (first electrode) of each of the first transistor T1, the second transistor T2, the third transistor T3, the fourth transistor T4, the fifth transistor T5, and the sixth transistor T6 may be one of a source region and a drain region, and a second terminal (second electrode) thereof may be the other one.

At least one of the first transistor T1, the second transistor T2, the third transistor T3, the fourth transistor T4, the fifth transistor T5, and the sixth transistor T6 may be a p-channel metal oxide semiconductor field-effect transistor (MOSFET) (PMOS), and the rest may be n-channel MOSFETs (NMOS). For example, the fifth transistor T5 may be a PMOS, and the first transistor T1, the second transistor T2, the third transistor T3, the fourth transistor T4, and the sixth transistor T6 may be NMOS. Alternatively, the fifth transistor T5 and the sixth transistor T6 may be PMOS, and the first transistor T1, the second transistor T2, the third transistor T3, and the fourth transistor T4 may be NMOS. Alternatively, all transistors may be NMOS or all transistors may be PMOS. In one or more embodiments, at least one of the transistors may be a thin-film transistor (TFT) with a structure that allows for flexibility and is configured to control pixels in a display panel.

At least one of the transistors may be a transistor having a low-temperature polycrystalline silicon (LTPS) semiconductor layer, and the rest may be transistors having oxide semiconductor layers. For example, the fifth transistor T5 may include a semiconductor layer including polycrystalline silicon having high reliability, and each of the remaining transistors T1-T4 may include an oxide semiconductor layer having the characteristics of high carrier mobility and low leakage current. Below, a case where the fifth transistor T5 is a PMOS including a silicon semiconductor layer and the remaining transistors T1-T4 are NMOS including an oxide semiconductor layer is described.

The pixel circuit PC may be electrically connected to gate lines configured to transmit signals to the gate electrodes of the transistors. For example, the pixel circuit PC may be connected to a scan line GWL configured to transmit a scan signal GW, an initialization gate line GBL configured to transmit an initialization signal GB, a reference gate line GRL configured to transmit a reference signal GR, a first emission control line EML configured to transmit a first emission control signal EM, a second emission control line EMBL configured to transmit a second emission control signal EMB, and a data line DL configured to transmit a data signal DATA. Additionally, the pixel circuit PC may be connected to the driving voltage line PL configured to transmit the first power voltage ELVDD, a reference voltage line VRL configured to transmit a reference voltage VREF, and an initialization voltage line VL configured to transmit an initialization voltage VINT.

The first transistor T1 operates as a driving transistor that controls on and off states of light-emitting diode LED, by providing power from the driving voltage line PL to the light-emitting diode LED or blocking the power supply, based on the data signal DATA applied to the gate of the first transistor T1. Specifically, the first transistor T1 may be electrically connected between the driving voltage line PL and a second node N2. The first transistor T1 may include a first gate electrode G1 connected to a first node N1, the first terminal electrically connected to the driving voltage line PL, and a second terminal connected to the second node N2. The first terminal may be a drain region (or a drain electrode) D1 and the second terminal may be a source region (or a source electrode) S1. The first terminal of the first transistor T1 may be electrically connected to the driving voltage line PL via the fifth transistor T5, and the second terminal of the first transistor T1 may be electrically connected to a pixel electrode of the light-emitting diode LED. The first transistor T1 may receive the data signal DATA according to a switching operation of the second transistor T2 and control the amplitude of a driving current Id flowing to the light-emitting diode LED.

The second transistor T2 operates a data writing transistor that provides the data signal DATA to the first transistor T1 or prevents it from being delivered to the first transistor T1, based on the scan signal GW applied to the gate of the second transistor T2. Specifically, the second transistor T2 may be electrically connected between the data line DL and the first node N1. The second transistor T2 may include a gate electrode connected to the scan line GWL, a first terminal connected to a data line DL, and a second terminal connected to a first node N1. The second transistor T2 may be turned on by the scan signal GW transmitted to the scan line GWL to electrically connect the data line DL to the first node N1, to thereby transmit the data signal DATA from the data line DL to the first node N1.

The third transistor T3 operates as a first initialization transistor that applies the reference voltage VREF to the gate of the first transistor T1, or disconnects the reference voltage VREF from the gate of the first transistor T1, based on the reference signal GR applied to the gate of the third transistor T3. The third transistor T3 may be electrically connected between the first node N1 and the reference voltage line VRL. The third transistor T3 may include a gate electrode connected to the reference gate line GRL, a first terminal connected to the first node N1, and a second terminal connected to the reference voltage line VRL. The third transistor T3 may be turned on by the reference signal GR transmitted to the reference gate line GRL, and may transmit the reference voltage VREF from the reference voltage line VRL to the first node N1.

The fourth transistor T4 operates as a second initialization transistor that applies the initialization voltage VINT to an input node of the light-emitting diode LED, based on the initialization gate line GBL applied to the gate of the fourth transistor T4. The fourth transistor T4 may be electrically connected between the first transistor T1 and the initialization voltage line VL. The fourth transistor T4 may include a gate electrode connected to the initialization gate line GBL, and a first terminal connected to a second terminal of the sixth transistor T6 and the light-emitting diode LED, and a second terminal connected to the initialization voltage line VL. The fourth transistor T4 may be turned on by the initialization signal GB transmitted to the initialization gate line GBL, and may transmit the initialization voltage VINT from the initialization voltage line VL to the pixel electrode of the light-emitting diode LED. That is, the fourth transistor T4 may initialize an electric potential of the pixel electrode of the light-emitting diode LED to the initialization voltage VINT.

The fifth transistor T5 operates a light emission control transistor that provides or blocks the power supply from the driving voltage line PL to the drain of the first transistor T1, based on the first emission control signal EM applied to the gate of the fifth transistor T5. The fifth transistor T5 may be electrically connected between the driving voltage line PL and the first transistor T1. The fifth transistor T5 may include a gate electrode connected to the first emission control line EML, a first terminal connected to the driving voltage line PL, and a second terminal connected to the first terminal of the first transistor T1. The fifth transistor T5 may be turned on or off according to the first emission control signal EM from the first emission control line EML.

The sixth transistor T6 operates as an operation control transistor or a switch that connects the first transistor T1 to the light-emitting diode LED or disconnect them, based on the second emission control signal EMB applied to the gate of the sixth transistor T6. The sixth transistor T6 may include a gate electrode connected to the second emission control line EMBL, a first terminal connected to the second node N2, and a second terminal connected to the light-emitting diode LED. The sixth transistor T6 may be turned on by the second emission control signal EMB from the second emission control line EMBL, so as to electrically connect the second node N2 to the pixel electrode of the light-emitting diode LED.

For reference, FIG. 7 illustrates the fifth transistor T5 and the sixth transistor T6 operating in response to two different emission control signals (e.g., the first emission control signal EM and the second emission control signal EMB), but the disclosure is not limited thereto. For example, the fifth transistor T5 and the sixth transistor T6 may operate in response to a same emission control signal.

For reference, the reference signal GR may be substantially synchronized with the scan signal GW of the pixel circuit PC located in a previous row. The initialization signal GB may be substantially synchronized with the scan signal GW. Alternatively, the initialization signal GB may be substantially synchronized with the scan signal GW or the reference signal GR of the pixel circuit PC located in a next row.

The storage capacitor Cst may be electrically connected between the first node N1 and the second node N2. That is, the pixel circuit PC included in a display panel according to the present embodiment may be a source follower type circuit in which the storage capacitor Cst is connected between the first node N1 and the second node N2. A first storage electrode CEs1 of the storage capacitor Cst may be connected to the first node N1, and a second storage electrode CEs2 thereof may be connected to the second node N2. The storage capacitor Cst may store a voltage corresponding to a threshold voltage of the first transistor T1 and the data signal DATA.

The hold capacitor Chd may be connected between the driving voltage line PL and the second node N2. A first hold electrode CEh1 of the hold capacitor Chd may be electrically connected to the driving voltage line PL, and a second hold electrode CEh2 of the hold capacitor Chd may be electrically connected to the second node N2. The hold capacitor Chd may allow a voltage of the second node N2 of the first transistor T1 not to fluctuate and have a constant voltage when a peripheral signal fluctuates.

The light-emitting diode LED may include a pixel electrode electrically connected to the second node N2 and a common electrode above the pixel electrode, and the common electrode may be supplied with the second power supply voltage ELVSS. The common electrode may be a single body with respect to a plurality of light-emitting diodes LED.

In FIG. 7, the pixel circuit PC including six transistors and two capacitors is illustrated, but the disclosure is not limited thereto. For example, the pixel circuit PC may include five transistors and two capacitors. The pixel circuit PC may include seven transistors and one capacitor.

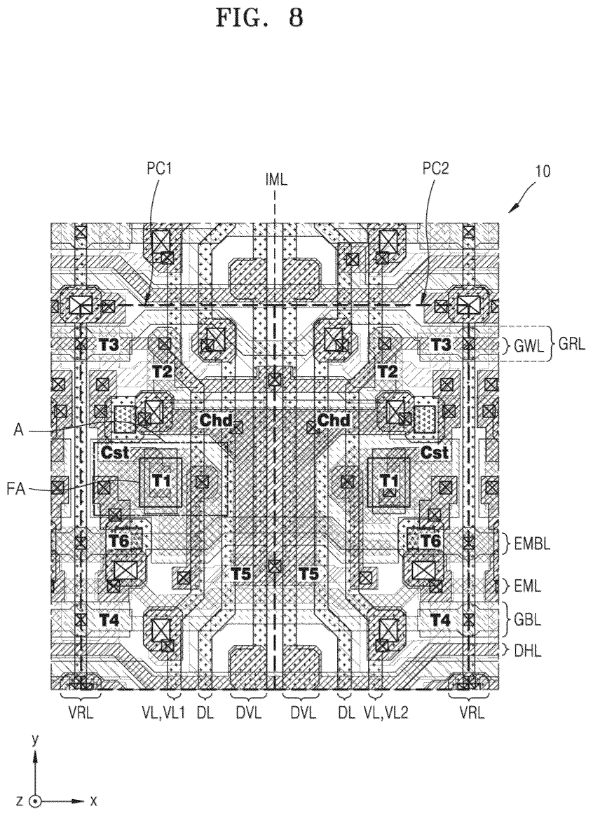

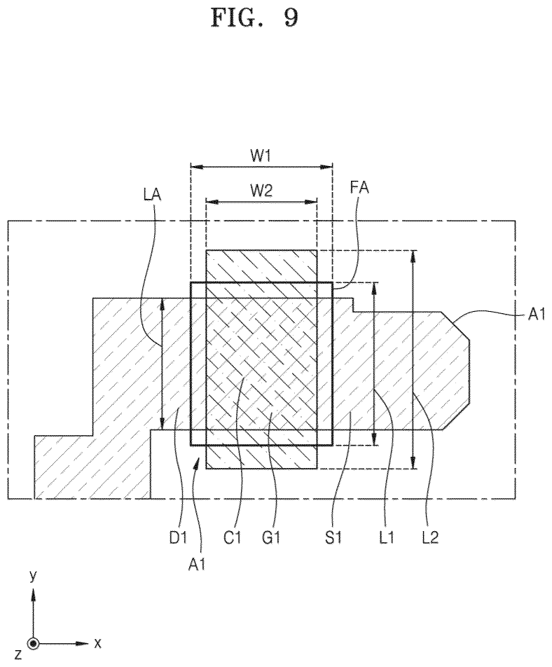

FIG. 8 is a layout diagram schematically showing positions of transistors, capacitors, etc. in pixels arranged in a display area of the display panel of FIG. 6. FIG. 9 is a layout diagram schematically showing positions of a first transistor, a second connection electrode, and an unevenness area in the pixels arranged in the display area of the display panel of FIG. 8. For convenience of description, FIG. 8 illustrates two pixel circuits arranged in a same row in the first direction (x-axis direction), for example, a first pixel circuit PC1 and a second pixel circuit PC2. However, the disclosure is not limited thereto. In addition, in FIG. 8, the first pixel circuit PC1 and the second pixel circuit PC2 are illustrated as being mirror-symmetrical with respect to an imaginary line IML extending in the second direction (y-axis direction) therebetween, but the disclosure is not limited thereto. The display panel 10 may include a plurality of pixel circuits arranged in rows in the first direction (x-axis direction) and columns in the second direction (y-axis direction).

As illustrated in FIGS. 8 and 9, each of the first pixel circuit PC1 and the second pixel circuit PC2 may include transistors and capacitors. For example, each of the first pixel circuit PC1 and the second pixel circuit PC2 may include the first transistor T1 to the sixth transistor T6, the storage capacitor Cst, and the hold capacitor Chd described above with reference to FIG. 7.

Gate lines electrically connected to the first pixel circuit PC1 and the second pixel circuit PC2, such as the scan line GWL, the initialization gate line GBL, the reference gate line GRL, the first emission control line EML, and the second emission control line EMBL, may extend approximately in the first direction (x-axis direction). In addition, a horizontal connection line DHL may also extend approximately in the first direction (x-axis direction).

The first pixel circuit PC1 may be electrically connected to the data line DL passing through the first pixel circuit PC1, and the second pixel circuit PC2 may be electrically connected to the data line DL passing through the second pixel circuit PC2. The data line DL may extend approximately in the second direction (y-axis direction). The data line DL electrically connected to the first pixel circuit PC1 and the data line DL electrically connected to the second pixel circuit PC2 may be symmetrical to each other with respect to the imaginary line IML described above.

The first pixel circuit PC1 may be electrically connected to voltage lines passing through the first pixel circuit PC1, such as the reference voltage line VRL and the initialization voltage line VL. The second pixel circuit PC2 may be electrically connected to voltage lines passing through the second pixel circuit PC2, such as the reference voltage line VRL and the initialization voltage line VL. The reference voltage line VRL and the initialization voltage line VL electrically connected to the first pixel circuit PC1 may be symmetrical with respect to the reference voltage line VRL and the initialization voltage line VL electrically connected to the second pixel circuit PC2 with respect to the imaginary line IML. The reference voltage line VRL and the initialization voltage line VL may each extend approximately in the second direction (y-axis direction). For convenience, the initialization voltage line VL passing through the first pixel circuit PC1 may be referred to as a first initialization voltage line VL1 and the initialization voltage line VL passing through the second pixel circuit PC2 may be referred to as a second initialization voltage line VL2. That is, the first initialization voltage lines VL1 and the second initialization voltage lines VL2 extending in the second direction (y-axis direction) may be arranged alternately in the first direction (x-axis direction).

A vertical connection line DVL may also extend along the second direction (y-axis direction). The vertical connection line DVL may correspond to a portion of a data transmission line DTL, for example, any one of a first vertical connection line, a second vertical connection line, a third vertical connection line, a first additional vertical connection line, a second additional vertical connection line, and a third additional vertical connection line. The vertical connection line DVL may be electrically connected to the data line DL of pixel circuits arranged in a different column from the first pixel circuit PC1 and the second pixel circuit PC2 illustrated in FIG. 8, so as to transmit data signals to the pixel circuits arranged in the different column. Alternatively, if the first pixel circuit PC1 or the second pixel circuit PC2 is not located near a corner of the display area DA but rather in a center of the display area DA, the vertical connection line DVL may be a dummy line to which no electrical signal is applied, or may be a dummy line to which a constant electrical signal is applied as needed.

For reference, the horizontal connection line DHL may correspond to a portion of the data transmission line DTL, for example, one of a first horizontal connection line, a second horizontal connection line, or a third horizontal connection line. In this case, the horizontal connection line DHL may be electrically connected to the data line DL of the pixel circuits arranged in a different column from the first pixel circuit PC1 and the second pixel circuit PC2 illustrated in FIG. 8, together with the vertical connection line DVL, so as to transmit data signals to the pixel circuits arranged in the different column. Alternatively, if the first pixel circuit PC1 or the second pixel circuit PC2 is not located near a corner of the display area DA but rather in a center of the display area DA, the horizontal connection line DHL may be a dummy line to which no electrical signal is applied, or may be a dummy line to which a constant electrical signal is applied as needed.

As illustrated in FIG. 9, at least a portion of the first transistor T1 of each of the first pixel circuit PC1 and the second pixel circuit PC2 may overlap the unevenness area FA. The unevenness area FA may completely overlap a channel region C1 of the first semiconductor layer A1 of the first transistor T1 described later when viewed in a plan view. Additionally, the unevenness area FA may be arranged to overlap the first gate electrode G1.

A first width W1 of the unevenness area FA may be greater than a second width W2 of the first gate electrode G1. Additionally, the first width W1 of the unevenness area FA may be greater than a width of the channel region C1 of the first semiconductor layer A1. A first length L1 of the unevenness area FA may be equal to or smaller than a second length L2 of the first gate electrode G1. Additionally, the first length L1 may be equal to or greater than a third length LA of the first semiconductor layer A1. In the above case, when viewed in plan view, the channel region C1 of the first semiconductor layer A1 may be arranged inside the unevenness area FA. Additionally, in plan view, at least a portion of the source region S1 of the first semiconductor layer A1 may overlap the unevenness area FA. Accordingly, the unevenness area FA may provide unevenness to the channel region C1 of the first semiconductor layer A1.

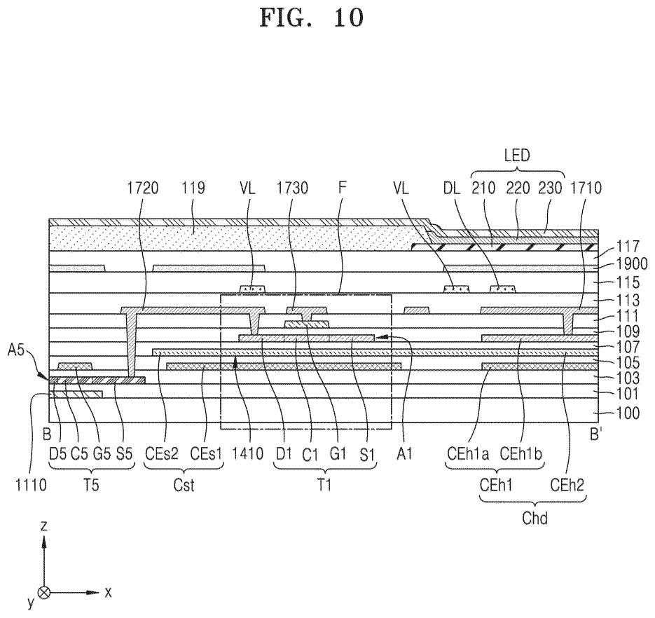

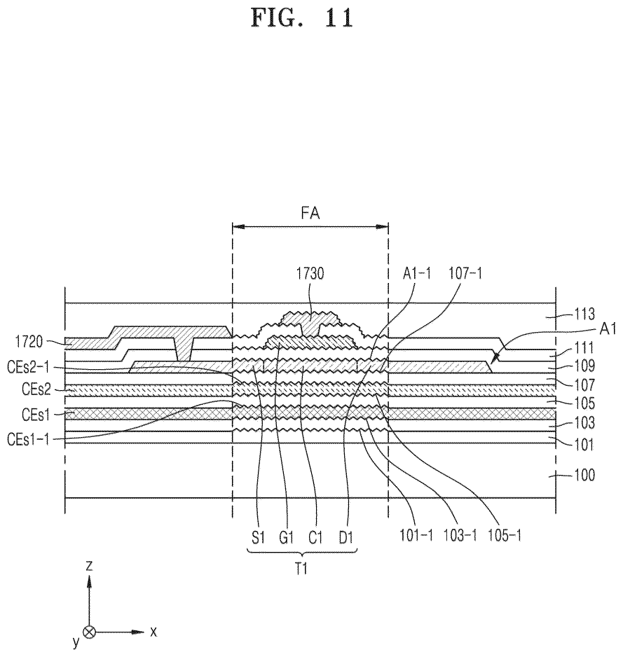

FIG. 10 is a cross-sectional view schematically illustrating a cross-section taken along line B-B′ of FIG. 6. FIG. 11 is an enlarged cross-sectional view illustrating region F of FIG. 10. As illustrated in FIG. 10, the display panel 10 may include a circuit layer including transistors and capacitors arranged on the substrate 100 and a display element layer arranged on the circuit layer and including the light-emitting diode LED. The circuit layer may include transistors and capacitors as described above with reference to FIGS. 7 and 8. FIG. 10 illustrates the first transistor T1, the fifth transistor T5, the storage capacitor Cst, and the hold capacitor Chd.

Referring to FIGS. 10 and 11, a lower metal layer 1110 may be arranged on the substrate 100. The lower metal layer 1110 may include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the lower metal layer 1110 may have a single layer structure including molybdenum, a double layer structure in which a molybdenum layer and a titanium layer are stacked, or a triple layer structure in which a titanium layer, an aluminum layer, and a titanium layer are stacked.

The lower metal layer 1110 may have a voltage level of a constant voltage. For example, the lower metal layer 1110 may have a same voltage level as the driving voltage line PL described above with reference to FIG. 7. That is, the first power voltage ELVDD may be applied to the lower metal layer 1110. For this purpose, the lower metal layer 1110 may be electrically connected to, for example, a portion of the driving voltage line PL or the first power supply line 15 in the peripheral area PA. The lower metal layer 1110 may at least partially shield light that passes to a fifth semiconductor layer A5 of the fifth transistor T5 and protect the fifth transistor T5 from electrostatic discharge ESD.

A buffer layer 101 may be arranged on the lower metal layer 1110 to cover the lower metal layer 1110. The buffer layer 101 may be an inorganic insulating layer including an inorganic insulating material such as silicon oxide, silicon nitride, and/or silicon oxynitride. The buffer layer 101 may have a single-layer structure or a multi-layer structure.

Referring to FIG. 11, at least a portion of the buffer layer 101 may include a first unevenness 101-1 corresponding to the unevenness area FA. In the present disclosure, an unevenness of a layer may refer to an average deviation of its surface profile from a mean line of the layer. For example, the first unevenness 101-1 may be quantified as an arithmetic average roughness (Ra) of absolute values of surface height deviations from the mean line of the butter layer 101. The first unevenness 101-1 may range from 10 nm to 50 nm in Ra when light or medium etching is applied to the buffer layer 101, or from 50 nm to 100 nm in Ra when heavy etching is applied to the butter layer 101. The first unevenness 101-1 may be formed by laser etching, spraying an etchant, mechanical polishing, etc. on at least a portion of the buffer layer 101. The first unevenness 101-1 may be arranged to correspond to the first semiconductor layer A1. That is, the first semiconductor layer A1 may be arranged on the first unevenness 101-1.

A silicon semiconductor layer may be arranged on the buffer layer 101. In FIG. 10, the fifth transistor T5 is illustrated as including a silicon semiconductor layer. That is, in FIG. 10, the fifth semiconductor layer A5 included in the fifth transistor T5 positioned on the buffer layer 101 is illustrated. The fifth semiconductor layer A5 may include a channel region C5 and doped regions S5, D5 doped with impurities and arranged on both sides of the channel region C5. One of the doping regions S5, D5 of the fifth semiconductor layer A5 may be a source region and the other may be a drain region.

A first gate insulating layer 103 may be arranged on the fifth semiconductor layer A5 to cover the fifth semiconductor layer A5. The first gate insulating layer 103 may be an inorganic insulating layer including an inorganic insulating material such as silicon oxide, silicon nitride, and/or silicon oxynitride. The first gate insulating layer 103 may have a single-layer structure or a multi-layer structure. A second unevenness 103-1 may be arranged to correspond to the first unevenness 101-1 in the first gate insulating layer 103. The second unevenness 103-1 may be formed by the first unevenness 101-1 when the first gate insulating layer 103 is formed, or may be arranged on the first gate insulating layer 103 in a similar manner to the first unevenness 101-1.

A fifth gate electrode G5 may be arranged on the first gate insulating layer 103. A position of the fifth gate electrode G5 may overlap a position of the channel region C5 of the fifth semiconductor layer A5 in the x-direction. In addition to the fifth gate electrode G5, a sub-layer of the first storage electrode CEs1 of the storage capacitor Cst and the first hold electrode CEh1 of the hold capacitor Chd, for example, a first lower hold electrode CEh1a, may be arranged on the first gate insulating layer 103.

The fifth gate electrode G5, the first storage electrode CEs1 of the storage capacitor Cst, and the first lower hold electrode CEh1a of the hold capacitor Chd may include a same material. The fifth gate electrode G5, the first storage electrode CEs1 of the storage capacitor Cst, and the first lower hold electrode CEh1a of the hold capacitor Chd may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layer structure or a multi-layer structure including these materials. For example, the fifth gate electrode G5, the first storage electrode CEs1 of the storage capacitor Cst, and the first lower hold electrode CEh1a of the hold capacitor Chd may have a single-layer structure including molybdenum or a multi-layer structure of molybdenum/aluminum/molybdenum. The first storage electrode CEs1 may include a third unevenness CEs1-1 corresponding to the unevenness area FA. The third unevenness CEs1-1 may be formed by an unevenness arranged on a lower portion of the third unevenness CEs1-1 when the first storage electrode CEs1 is formed, or may be arranged on the first storage electrode CEs1 in a similar manner to the second unevenness 103-1.

A second gate insulating layer 105 may be arranged on the fifth gate electrode G5, the first storage electrode CEs1 of the storage capacitor Cst, and the first lower hold electrode CEh1a of the hold capacitor Chd to cover the same. The second gate insulating layer 105 may be an inorganic insulating layer including an inorganic insulating material such as silicon oxide, silicon nitride, and/or silicon oxynitride. The second gate insulating layer 105 may have a single-layer structure or a multi-layer structure. If necessary, the second gate insulating layer 105 may include a material different from that of the first gate insulating layer 103. For example, the first gate insulating layer 103 may include silicon oxide, and the second gate insulating layer 105 may include silicon nitride. The second gate insulating layer 105 may include a fourth unevenness 105-1 corresponding to the unevenness area FA. The fourth unevenness 105-1 may be formed by an unevenness arranged under the fourth unevenness 105-1 when the second gate insulating layer 105 is formed, or may be arranged on the second gate insulating layer 105 in a similar manner to the second unevenness 103-1.

A conductive layer (1410, hereinafter referred to as a fifth conductive layer for convenience) may be arranged on the second gate insulating layer 105. A position of the fifth conductive layer 1410 may overlap a position of the first storage electrode CEs1 of the storage capacitor Cst and a position of the first lower hold electrode CEh1a of the hold capacitor Chd in the x-direction. The fifth conductive layer 1410 may include the second storage electrode CEs2 of the storage capacitor Cst and the second hold electrode CEh2 of the hold capacitor Chd. That is, a portion of the fifth conductive layer 1410 may be the second storage electrode CEs2 of the storage capacitor Cst, and another portion of the fifth conductive layer 1410 may be the second hold electrode CEh2 of the hold capacitor Chd. As such, the second storage electrode CEs2 of the storage capacitor Cst and the second hold electrode CEh2 of the hold capacitor Chd may be a single body. The second storage electrode CEs2 may include a fifth unevenness CEs2-1 to correspond to the unevenness area FA. The fifth unevenness CEs2-1 may be formed by an unevenness arranged under the fifth unevenness CEs2-1 when the second storage electrode CEs2 is formed, or may be arranged on the second storage electrode CEs2 in a similar manner to the third unevenness CEs1-1.

The fifth conductive layer 1410 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layer structure or a multi-layer structure including these materials. For example, the fifth conductive layer 1410 may have a single-layer structure including molybdenum or a multi-layer structure of molybdenum/aluminum/molybdenum.

A first interlayer insulating layer 107 may be arranged on the fifth conductive layer 1410 to cover the fifth conductive layer 1410. The first interlayer insulating layer 107 may be an inorganic insulating layer including an inorganic insulating material such as silicon oxide, silicon nitride, and/or silicon oxynitride. The first interlayer insulating layer 107 may have a single-layer structure or a multi-layer structure. For example, the first interlayer insulating layer 107 may have a stacked structure of a layer including silicon oxide and a layer including silicon nitride. The first interlayer insulating layer 107 may include a sixth unevenness 107-1 corresponding to the unevenness area FA. The sixth unevenness 107-1 may be formed by an unevenness arranged under the sixth unevenness 107-1 when the first interlayer insulating layer 107 is formed, or may be arranged on the first interlayer insulating layer 107 in a similar manner to the first unevenness 101-1.

The first semiconductor layer A1 of the first transistor T1 and a first upper hold electrode CEH1b of the hold capacitor Chd may be arranged on the first interlayer insulating layer 107. The first semiconductor layer A1 of the first transistor T1 and the first upper hold electrode CEH1b of the hold capacitor Chd may both include a same material. Specifically, the first semiconductor layer A1 of the first transistor T1 and the first upper hold electrode CEH1b of the hold capacitor Chd may include an oxide semiconductor. The oxide semiconductor may be an oxide semiconductor including at least one element selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the oxide semiconductor may include InSnZnO (ITZO) or InGaZnO (IGZO).

The first semiconductor layer A1 may include the channel region C1 and conductive doped regions S1, D1 arranged on both sides of the channel region C1. One of the doping regions S1, D1 may be a source region and the other may be a drain region. The first semiconductor layer A1 may be arranged on a different layer from the fifth semiconductor layer A5 described above. A vertical distance from the substrate 100 to the first semiconductor layer A1 may be greater than a vertical distance from the substrate 100 to the fifth semiconductor layer A5.

The first semiconductor layer A1 as described above may have a seventh unevenness A1-1. The first semiconductor layer A1 may include the seventh unevenness A1-1 on at least one surface thereof. For example, the seventh unevenness A1-1 may be arranged on at least one of a first surface of the first semiconductor layer A1 facing the first gate electrode G1 and a second surface of the first semiconductor layer A1 facing the first surface. For convenience of description, the following description will focus on a case where the seventh unevenness A1-1 is arranged on both the first surface and the second surface.

The seventh unevenness A1-1 may have a zigzag shape, a s-shaped curve, a wavy shape, or a serpentine shape. For example, the seventh unevenness A1-1 may have at least one unevenness and at least one groove. In this case, when the seventh unevenness A1-1 has a plurality of unevennesses and a plurality of grooves, at least one of the shape and size of one of the plurality of unevennesses and the other of the plurality of unevennesses may be different from each other, or at least one of the shape and size of one of the plurality of grooves and the other of the plurality of grooves may be different from each other. The plurality of grooves may form rugged and irregular topologies on the first semiconductor layer A1. As another embodiment, the plurality of unevennesses may have almost the same shape and size, and the plurality of grooves may have almost the same shape and size. For convenience of description, the seventh unevenness A1-1 will be described in detail below, focusing on a case where the seventh unevenness A1-1 is formed on both the first surface and the second surface of the first semiconductor layer A1.

The seventh unevenness A1-1 may be formed by at least one unevenness arranged below the seventh unevenness A1-1. In particular, the seventh unevenness A1-1 may be formed on at least one of an upper surface and a lower surface of the first semiconductor layer A1. Additionally, the seventh unevenness A1-1 may be formed in the channel region C1 of the first semiconductor layer A1. The seventh unevenness A1-1 may be formed in at least one of the doping regions S1, D1. The seventh unevenness A1-1 may reduce current sensitivity of the first transistor T1 by increasing an effective channel length of the first transistor T1 by bending the channel region C1 of the first semiconductor layer A1. Accordingly, when a low voltage is applied to the first semiconductor layer A1, a current does not change rapidly when a voltage is varied, thereby preventing ab abrupt change in the intensity of light emitted by a pixel.

In order to form the seventh unevenness A1-1 as described above, as illustrated in the drawing, instead of forming all of the first unevenness 101-1 to the sixth unevenness 107-1 as illustrated in the drawing, at least one of the first unevenness 101-1 to the sixth unevenness 107-1 may be formed. That is, the seventh unevenness A1-1 may be formed by forming an unevenness in at least one of layers arranged under the first semiconductor layer A1 and arranged in the unevenness area FA corresponding to the channel region C1 of the first semiconductor layer A1. Specifically, the seventh unevenness A1-1 may be formed by forming the second unevenness 103-1 to the sixth unevenness 107-1, the third unevenness CEs1-1 to the sixth unevenness 107-1, the fourth unevenness 105-1 to the sixth unevenness 107-1, the fifth unevenness CEs2-1 and the sixth unevenness 107-1, or the sixth unevenness 107-1. The range of unevenness from the first unevenness 101-1 to the seventh unevenness A1-1 may vary from 10 nm to 100 nm in Ra. These unevenness values may be consistent or nearly identical across the range. For example, the difference in unevenness between the first unevenness 101-1 and the seventh unevenness A1-1 may be less than 10% of the average unevenness value for the entire range from the first to the seventh unevenness.

In the above case, an unevenness layer may be a portion of at least one of the layers arranged under the first semiconductor layer A1. For example, the unevenness layer may be a portion of at least one of the buffer layer 101, the first gate insulating layer 103, the first storage electrode CEs1, the second gate insulating layer 105, the second storage electrode CEs2, and the first interlayer insulating layer 107 disposed under the first semiconductor layer A1. Along the entire longitudinal lengths of the buffer layer 101, the first gate insulating layer 103, the second gate insulating layer 105, and the first interlayer insulating layer 107, only a specific portion may exhibit unevenness. The position of this specific portion may overlap the position of the first transistor T1 in the longitudinal direction (i.e., the x-direction) and may extend beyond the length of the first transistor T1 by a predetermined longitudinal margin. A difference between an unevenness of the specific (uneven) portion and a remaining (even) portion of each of the above-mentioned layers, may range from 10 nm to 100 nm in Ra.

A position of the first upper hold electrode CEH1b of the hold capacitor Chd may overlap positions of the fifth conductive layer 1410 and the first lower hold electrode CEh1a of the hold capacitor Chd below the fifth conductive layer 1410, in the x-direction. The first upper hold electrode CEH1b of the hold capacitor Chd may be electrically connected to the first lower hold electrode CEh1a.

A third gate insulating layer 109 may be arranged on the first semiconductor layer A1 and the first upper hold electrode CEH1b of the hold capacitor Chd to cover the same. The third gate insulating layer 109 may be an inorganic insulating layer including an inorganic insulating material such as silicon oxide, silicon nitride, and/or silicon oxynitride. The third gate insulating layer 109 may have a single-layer structure or a multi-layer structure. For example, the third gate insulating layer 109 may have a single-layer structure including silicon oxide.

In FIG. 10, the third gate insulating layer 109 is illustrated as passing through a side surface of the first semiconductor layer A1 and contacting an upper surface of the first interlayer insulating layer 107, but the disclosure is not limited thereto. For example, the third gate insulating layer 109 may have substantially a same pattern and/or a same width as the first gate electrode G1 described later. That is, after forming an insulating layer for forming the third gate insulating layer 109 and forming a conductive layer for forming the first gate electrode G1 on the insulating layer, the insulating layer and the conductive layer may be patterned simultaneously into a same shape to form the third gate insulating layer 109 and the first gate electrode G1. In this case, the third gate insulating layer 109 may not be in contact with the upper surface of the first interlayer insulating layer 107.

The first gate electrode G1 may be arranged on the third gate insulating layer 109. In a plan view, the first gate electrode G1 may overlap the channel region C1 of the first semiconductor layer A1. The first gate electrode G1 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layer structure or multi-layer structure including such materials. For example, the first gate electrode G1 may have a three-layer structure of titanium layer/aluminum layer/titanium layer.

A second interlayer insulating layer 111 may be arranged on the first gate electrode G1 to cover the first gate electrode G1. The second interlayer insulating layer 111 may be an inorganic insulating layer including an inorganic insulating material such as silicon oxide, silicon nitride, and/or silicon oxynitride. The second interlayer insulating layer 111 may have a single-layer structure or a multi-layer structure. For example, the second interlayer insulating layer 111 may have a stacked structure of a layer including silicon oxide and a layer including silicon oxynitride.

A first connection electrode 1710, a second connection electrode 1720, and a third connection electrode 1730 may be arranged on the second interlayer insulating layer 111. The first connection electrode 1710, the second connection electrode 1720, and the third connection electrode 1730 may include a same material. That is, the first connection electrode 1710, the second connection electrode 1720, and the third connection electrode 1730 may be formed simultaneously from a same material. The first connection electrode 1710, the second connection electrode 1720, and the third connection electrode 1730 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layer structure or multi-layer structure including such materials. For example, the first connection electrode 1710, the second connection electrode 1720, and the third connection electrode 1730 may have a three-layer structure of titanium layer/aluminum layer/titanium layer.

A first organic insulating layer 113 may be arranged on the first connection electrode 1710, the second connection electrode 1720, and the third connection electrode 1730 to cover the same. The first organic insulating layer 113 may include an organic insulating material such as acrylic, benzocyclobutene (BCB), polyimide, or hexamethyldisiloxane (HMDSO).

The data line DL and the initialization voltage line VL may be arranged on the first organic insulating layer 113. The data line DL and the initialization voltage line VL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layer structure or a multi-layer structure including such materials. For example, the data line DL and the initialization voltage line VL may have a three-layer structure of titanium layer/aluminum layer/titanium layer.

A second organic insulating layer 115 may be arranged on the data line DL and the initialization voltage line VL to cover the same. The second organic insulating layer 115 may include an organic insulating material such as acrylic, BCB, polyimide, or HMDSO.

A voltage layer 1900 may be arranged on the second organic insulating layer 115. The voltage layer 1900 may have a voltage level of the driving voltage line PL. The voltage layer 1900 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single-layer structure or a multi-layer structure including such materials. For example, the voltage layer 1900 may have a three-layer structure of titanium layer/aluminum layer/titanium layer.

A third organic insulating layer 117 may be arranged on the voltage layer 1900 to cover the voltage layer 1900. The third organic insulating layer 117 may include an organic insulating material such as acrylic, BCB, polyimide, or HMDSO.

The light-emitting diode LED may be arranged on the third organic insulating layer 117. The light-emitting diode LED may include a pixel electrode 210, an intermediate layer 220, and a common electrode 230 on a third organic insulating layer 117.

The pixel electrode 210 may include a (semi)-light transmissive electrode or a reflective electrode. For example, the pixel electrode 210 may include a reflective layer including Ag, Mg, Al, Pt, Pd, Au, Ni, Nd, Ir, Cr or a compound thereof, and a transparent or semitransparent electrode layer positioned on the reflective layer. The transparent or semitransparent electrode layer may include at least one selected from the group consisting of indium tin oxide (ITO), indium zinc oxide (IZO), zinc oxide (ZnOₓ: ZnO or ZnO₂), indium oxide (In₂O₃), indium gallium oxide (IGO), and aluminum zinc oxide (AZO). For example, the pixel electrode 210 may have a three-layer structure of ITO/Ag/ITO.

A pixel definition film 119 may be arranged on the third organic insulating layer 117. The pixel definition film 119 may prevent arcs and the like from occurring at an edge of the pixel electrode 210 by covering the edge of the pixel electrode 210 and increasing a distance between the pixel electrode 210 and the common electrode 230 thereabove. That is, the pixel definition film 119 may have an opening to expose a central portion of the pixel electrode 210. The pixel definition film 119 may be formed by a method such as spin coating and by using one or more organic insulating materials selected from the group consisting of polyimide, polyamide, acrylic resin, benzocyclobutene, and phenol resin.

At least a portion of the intermediate layer 220 including an emission layer of the light-emitting diode LED may be arranged within an opening formed in the pixel definition film 119. A light-emitting area of the light-emitting diode LED may be defined by the opening. The intermediate layer 220 may include an emission layer. The emission layer may include an organic material including a fluorescent or phosphorescent material that emits red, green, blue, or white light. The emission layer may include a low-molecular organic material or a high-molecular organic material, and functional layers such as a hole transport layer (HTL), a hole injection layer (HIL), an electron transport layer (ETL), and an electron injection layer (EIL) may be selectively disposed below and above the emission layer.

Alternatively, the intermediate layer 220 may include a first stack including an emission layer and a functional layer, a second stack including an emission layer and a functional layer, and a charge generation layer between the first stack and the second stack. The charge generation layer may include a negative charge generation layer and a positive charge generation layer. A tandem type light-emitting diode LED having a plurality of emission layers formed by the negative charge generation layer and the positive charge generation layer may have even higher light-emitting efficiency.

The negative charge generation layer may include an n-type charge generation layer. The negative charge generation layer may be configured to supply electrons. The negative charge generation layer may include a host and a dopant. The host may include organic material. The dopant may include a metallic substance. The positive charge generation layer may be a p-type charge generation layer. The positive charge generation layer may be configured to supply holes. The positive charge generation layer may include a host and a dopant. The host may include organic material. The dopant may include a metallic substance.

The emission layer may have a patterned shape corresponding to the pixel electrode 210. Layers other than the emission layer included in the intermediate layer may be modified in various ways; for example, the layers may be a single body with respect to a plurality of pixel electrodes 210.

The common electrode 230 may include a light-transmitting electrode or a reflective electrode. For example, the common electrode 230 may include a transparent or semitransparent electrode and may include a metal thin film with a small work function including Li, Ca, Al, Ag, Mg or a compound thereof (e.g., LiF). Additionally, the common electrode 230 may further include a transparent conductive oxide (TCO) film such as ITO, IZO, ZnO, ZnO₂ or In₂O₃ positioned on a metal thin film.

The common electrode 230 may be formed as a single body over the entire display area DA to cover the display area DA, and may be arranged on top of the intermediate layer 220 and the pixel definition film 119. That is, each of the pixel electrodes 210 may be arranged to correspond to each light-emitting diode LED, and the common electrode 230 may be formed as a single body to correspond to a plurality of light-emitting diodes LED. The plurality of light-emitting diodes LED may share the common electrode 230, and a stacked structure of the pixel electrode 210, the intermediate layer 220, and the common electrode 230 may correspond to the light-emitting diode LED.

If needed, an encapsulating layer may be arranged over the light-emitting diodes LED. The encapsulating layer may include a first inorganic encapsulating layer, a second inorganic encapsulating layer, and an organic encapsulating layer therebetween.

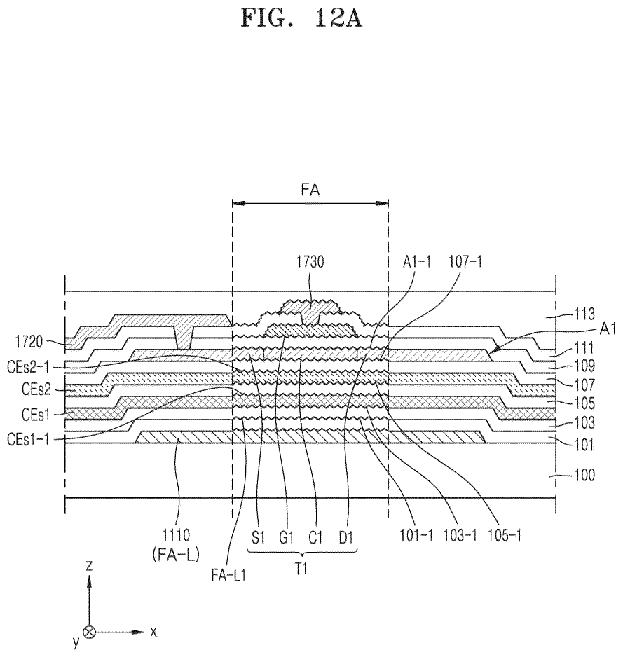

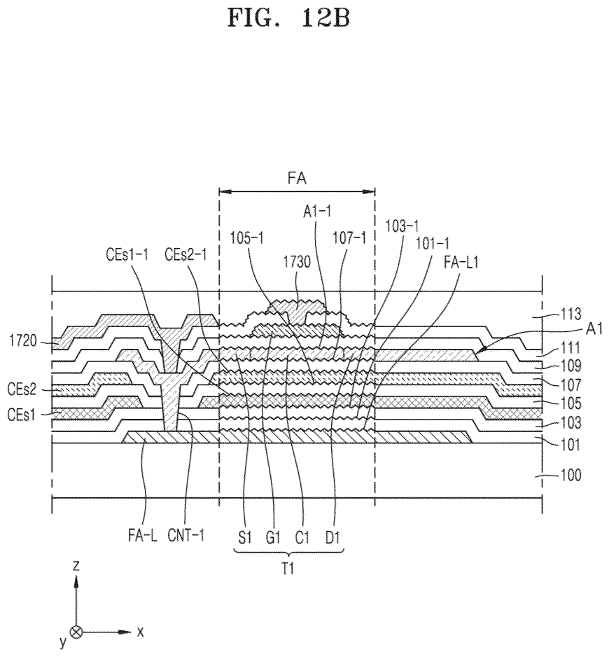

FIG. 12A is a cross-sectional view schematically illustrating a portion of a display area of a display panel, according to one or more embodiments. FIG. 12B is a cross-sectional view schematically illustrating a portion of a display area of a display panel, according to one or more embodiments. FIGS. 12A and 12B are schematic diagrams of a portion of a display panel corresponding to region F of FIG. 10, which may have a structure identical to or similar to the structure illustrated in FIG. 10. Below, description will focus on differences from the structure illustrated in FIG. 10.

Referring to FIG. 12A, an unevenness layer FA-L may be included to correspond to the unevenness area FA. For example, a planar shape of the unevenness layer FA-L may correspond to a planar shape of the unevenness area FA illustrated in FIG. 9. In this case, when the unevenness layer FA-L and the channel region C1 of the first semiconductor layer A1 are overlapped in a plan view, the channel region C1 of the first semiconductor layer A1 may be arranged within a plane region of the unevenness layer FA-L.

The unevenness layer FA-L may include a material identical to or similar to that of the lower metal layer 1110. As another embodiment, the unevenness layer FA-L may include polysilicon. The unevenness layer FA-L may be unconnected to other layers or may be electrically connected to a portion of the driving voltage line PL or the first power supply line 15. However, for the convenience of description, the following description will focus on a case where the unevenness layer FA-L is arranged in an electrically insulated form without being connected to other layers.

The unevenness layer FA-L may be covered by the buffer layer 101. At least a portion of one surface of the unevenness layer FA-L in contact with the buffer layer 101 may include a base unevenness FA-L1. The base unevenness FA-L1 may be formed in various ways. For example, if the unevenness layer FA-L includes a material identical to or similar to the lower metal layer 1110, it may be formed through laser etching, etchant spraying, or mechanical polishing. As another embodiment, when the unevenness layer FA-L includes polysilicon, the unevenness layer FA-L may be manufactured by arranging amorphous silicon (a-Si) on the substrate 100 and then annealing hydrogenated amorphous silicon by using an excimer laser. The base unevenness FA-L1 may be formed on at least one surface of the unevenness layer FA-L to which laser is radiated. As another embodiment, when the unevenness layer FA-L includes polysilicon, hydrogenated amorphous silicon (a-Si:H) may be disposed and then the hydrogenated amorphous silicon may be thermally annealed to form polysilicon. Afterwards, one surface of the polysilicon may be formed using an etchant such as potassium hydroxide to form the unevenness layer FA-L. The unevenness in the unevenness layer FA-L may include polysilicon with irregularities across the entire surface, or the irregularities may be localized to a specific area of the unevenness layer FA-L that overlaps the first transistor T1 in plan view. The unevenness may range from 10 nm to 100 nm in Ra. Here, a separate photoresist may be arranged in areas other than a portion where the unevenness layer FA-L is arranged, thereby preventing damage from the etchant.

The area of the unevenness layer FA-L, on which the base unevenness FA-L1 as described above is arranged, may be arranged to correspond to the unevenness area FA. That is, the planar shape of the unevenness layer FA-L may correspond to the unevenness area FA illustrated in FIG. 8. In this case, the channel region C1 of the first semiconductor layer A1 may be arranged to overlap the unevenness layer FA-L in a plan view.

In the above case, the first unevenness 101-1, the second unevenness 103-1, the third unevenness CEs1-1, the fourth unevenness 105-1, the fifth unevenness CEs2-1, the sixth unevenness 107-1, and the seventh unevenness A1-1 may be formed at positions corresponding to the base unevenness FA-L1 of each of the buffer layer 101, the first gate insulating layer 103, the first storage electrode CEs1, the second gate insulating layer 105, the second storage electrode CEs2, the first interlayer insulating layer 107, and the first semiconductor layer A1 arranged on the unevenness layer FA-L. Through this, the length of the channel region C1 of the first semiconductor layer A1 may be increased.

The third gate insulating layer 109, the second connection electrode 1720, the first gate electrode G1, the second interlayer insulating layer 111, and the first organic insulating layer 113 may be sequentially arranged on the first semiconductor layer A1. Other layers as illustrated in FIG. 8 may be sequentially stacked on the first organic insulating layer 113.

Referring to FIG. 12B, the unevenness layer FA-L, the buffer layer 101, the first gate insulating layer 103, the first storage electrode CEs1, the second gate insulating layer 105, the second storage electrode CEs2, the first interlayer insulating layer 107, and the first semiconductor layer A1 may be similar to those described with reference to FIG. 12A.

The source region S1 of the first semiconductor layer A1 may be directly connected to the unevenness layer FA-L through a first contact hole CNT-1. A conductive material may be filled in the first contact hole CNT-1, which may be the same material as the source region S1.The first storage electrode CEs1 and the second storage electrode CEs2 may be positioned so as not to overlap the first contact hole CNT-1 in plan view. For example, the first storage electrode CEs1 may have a first hole or a first groove arranged in an area where the first contact hole CNT-1 is arranged, and thus may not overlap the first contact hole CNT-1. As another embodiment, the first storage electrode CEs1 may not be arranged in the area where the first contact hole CNT-1 is arranged. In this case, the first storage electrode CEs1 may partially overlap or may not overlap the first semiconductor layer A1. In addition, the second storage electrode CEs2 may have a second hole or a second groove arranged in the area where the first contact hole CNT-1 is arranged, and thus may not overlap the second contact hole CNT-2. In another embodiment, the second storage electrode CEs2 may not be arranged in the area where the first contact hole CNT-1 is arranged. In this case, the second storage electrode CEs2 may partially overlap or may not overlap the first semiconductor layer A1. For convenience of description, the following description will focus on a case where the first storage electrode CEs1 includes a first hole and the second storage electrode CEs2 includes a second hole.

In the above case, the first contact hole CNT-1 may pass through the inside of the first hole and the second hole. The first contact hole CNT-1 may increase a subthreshold slope of the first transistor T1 by connecting the first semiconductor layer A1 included in the first transistor T1 to the unevenness layer FA-L. Through this, the voltage and current sensitivity of the first transistor T1 may be reduced.

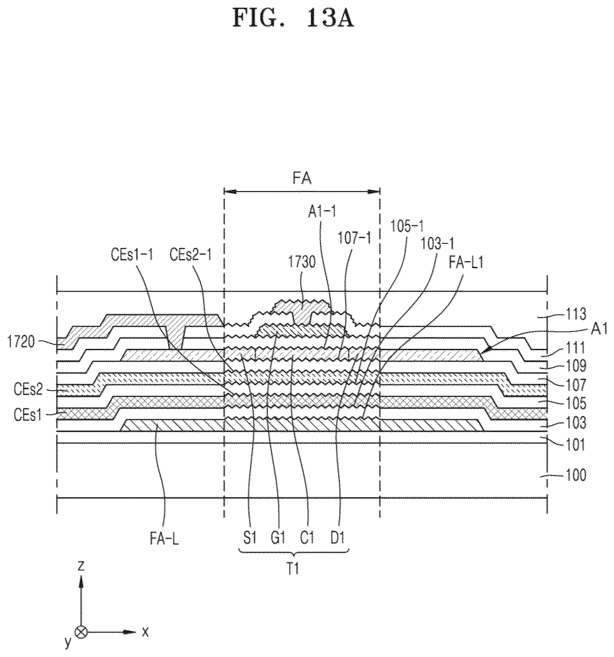

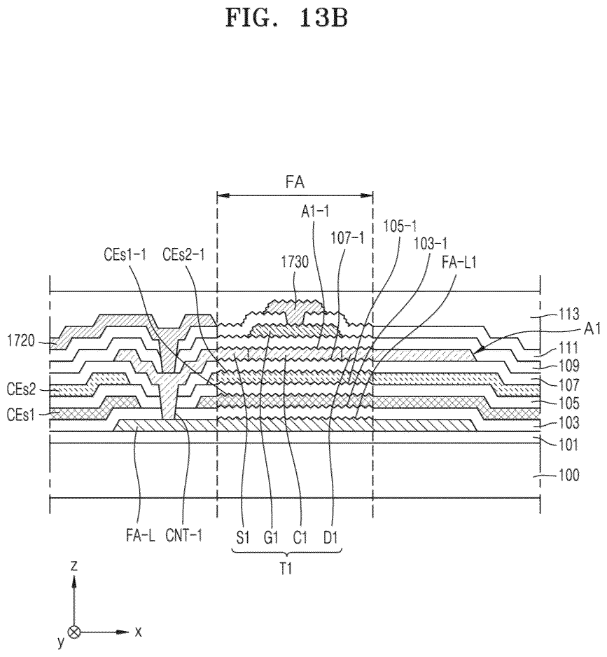

FIG. 13A is a cross-sectional view schematically illustrating a portion of a display area of a display panel, according to one or more embodiments. FIG. 13B is a cross-sectional view schematically illustrating a portion of a display area of a display panel, according to one or more embodiments. FIGS. 13A and 13B are schematic diagrams illustrating a portion of a display panel corresponding to region F of FIG. 10, which may have a structure identical to or similar to the structure illustrated in FIG. 10. Below, description will focus on differences from the structure illustrated in FIG. 10.

Referring to FIG. 13A, the display panel may include the unevenness layer FA-L, the buffer layer 101, the first gate insulating layer 103, the first storage electrode CEs1, the second gate insulating layer 105, the second storage electrode CEs2, the first interlayer insulating layer 107, the first semiconductor layer A1, the third gate insulating layer 109, the second interlayer insulating layer 111, the first gate electrode G1, the second connection electrode 1720, the third connection electrode 1730, and the first organic insulating layer 113. The layers arranged on the first organic insulating layer 113 as illustrated in FIG. 10 may be arranged on the first organic insulating layer 113 in FIG. 13A.

The unevenness layer FA-L may be arranged between the buffer layer 101 and the first gate insulating layer 103. The unevenness layer FA-L includes the base unevenness FA-L1 and may be shielded by the first gate insulating layer 103. The unevenness layer FA-L is the same or similar to that described with reference to FIGS. 12A and 12B, and thus detailed description thereof will be omitted.

In the case described above, the first gate insulating layer 103, the first storage electrode CEs1, the second gate insulating layer 105, the second storage electrode CEs2, the first interlayer insulating layer 107, and the first semiconductor layer A1 arranged on the base unevenness FA-L1 may include the second unevenness 103-1, the third unevenness CEs1-1, the fourth unevenness 105-1, the fifth unevenness CEs2-1, the sixth unevenness 107-1, and the seventh unevenness A1-1, respectively.

Referring to FIG. 13B, the unevenness layer FA-L may be directly connected to the first semiconductor layer A1. The unevenness layer FA-L and the first semiconductor layer A1 may be connected to each other through the first contact hole CNT-1. Additionally, the first storage electrode CEs1 and the second storage electrode CEs2 may have a structure that does not overlap the first contact hole CNT-1 in plan view, as described with reference to FIG. 12B.

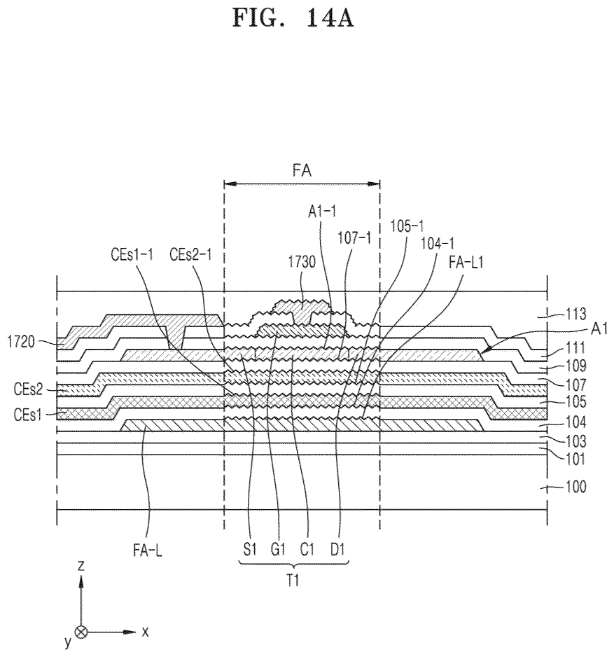

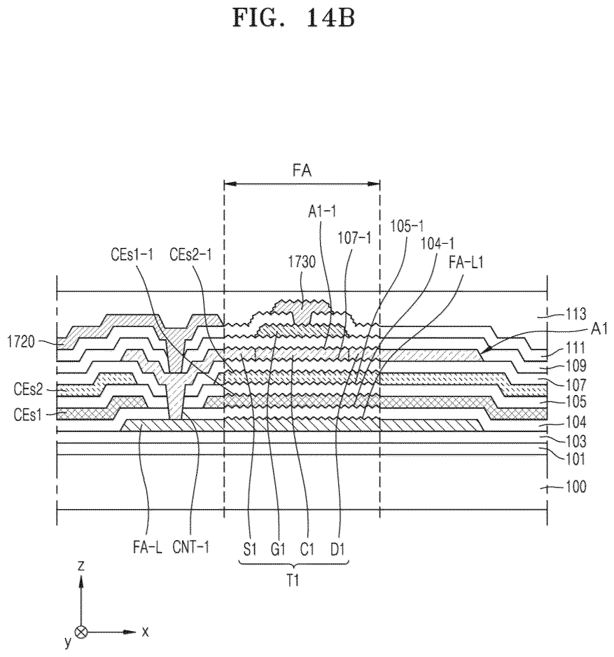

FIG. 14A is a cross-sectional view schematically illustrating a portion of a display area of a display panel, according to one or more embodiments; FIG. 14B is a cross-sectional view schematically illustrating a portion of a display area of a display panel, according to one or more embodiments; FIGS. 14A and 14B are schematic diagrams illustrating a portion of a display panel corresponding to region F of FIG. 10, which may have a structure identical to or similar to the structure illustrated in FIG. 10. Below, description will focus on differences from the structure illustrated in FIG. 10.

Referring to FIG. 14A, the display panel may include the unevenness layer FA-L, the buffer layer 101, the first gate insulating layer 103, the first storage electrode CEs1, the second gate insulating layer 105, the second storage electrode CEs2, the first interlayer insulating layer 107, the first semiconductor layer A1, the third gate insulating layer 109, the second interlayer insulating layer 111, the first gate electrode G1, the second connection electrode 1720, the third connection electrode 1730, and the first organic insulating layer 113. The layers arranged on the first organic insulating layer 113 as illustrated in FIG. 10 may be arranged on the first organic insulating layer 113 in FIG. 14A.

The unevenness layer FA-L may be arranged on the first gate insulating layer 103. The unevenness layer FA-L may include a base unevenness FA-L1. A first additional inorganic insulating layer 104 may be arranged on the unevenness layer FA-L, and the first additional inorganic insulating layer 104 may completely shield the unevenness layer FA-L. The first additional inorganic insulating layer 104 may include an eighth unevenness 104-1 arranged in a portion corresponding to the base unevenness FA-L1. The first additional inorganic insulating layer 104 may include a material identical to or similar to the first gate insulating layer 103. The unevenness layer FA-L is the same or similar to that described with reference to FIGS. 12A and 12B, and thus a detailed description will be omitted.

In the case described above, the first storage electrode CEs1, the second gate insulating layer 105, the second storage electrode CEs2, the first interlayer insulating layer 107, and the first semiconductor layer A1 arranged on the first additional inorganic insulating layer 104 may include the third unevenness CEs1-1, the fourth unevenness 105-1, the fifth unevenness CEs2-1, the sixth unevenness 107-1, and the seventh unevenness A1-1, respectively.

Referring to FIG. 14B, the unevenness layer FA-L may be directly connected to the first semiconductor layer A1. The unevenness layer FA-L and the first semiconductor layer A1 may be connected to each other through the first contact hole CNT-1. Additionally, the first storage electrode CEs1 and the second storage electrode CEs2 may have a structure that does not overlap the first contact hole CNT-1 in plan view, as described with reference to FIG. 12B. The first storage electrode CEs1 and the second storage electrode CEs2 may respectively have a first hole and a second hole having a first contact hole CNT-1 disposed therein.

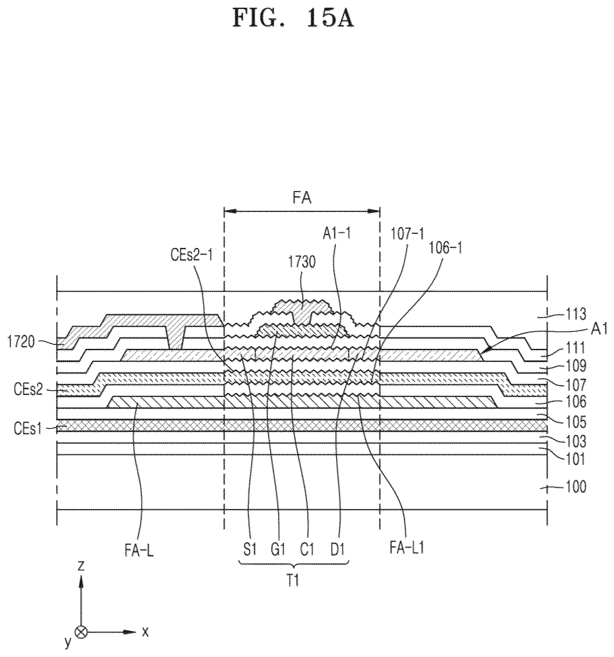

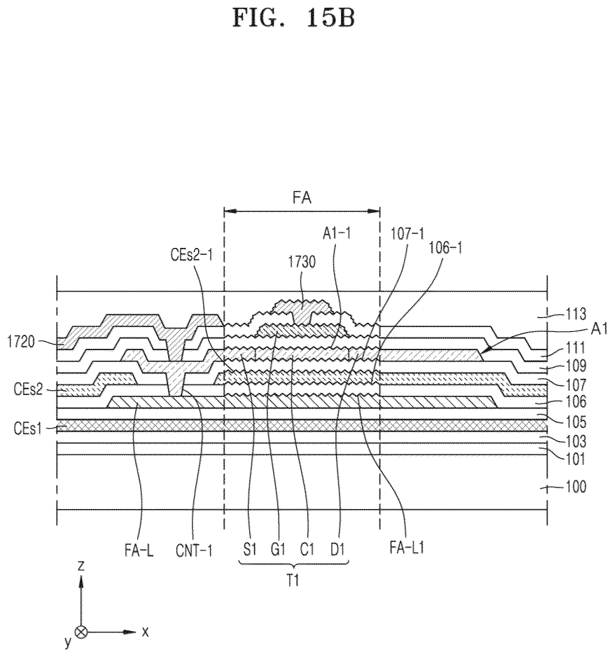

FIG. 15A is a cross-sectional view schematically illustrating a portion of a display area of a display panel, according to one or more embodiments. FIG. 15B is a cross-sectional view schematically illustrating a portion of a display area of a display panel, according to one or more embodiments. FIGS. 15A and 15B are schematic diagrams illustrating a portion of a display panel corresponding to region F of FIG. 10, which may have a structure identical to or similar to the structure illustrated in FIG. 10. Below, description will focus on differences from the structure illustrated in FIG. 10.

Referring to FIG. 15A, the display panel may include the unevenness layer FA-L, the buffer layer 101, the first gate insulating layer 103, the first storage electrode CEs1, the second gate insulating layer 105, the second storage electrode CEs2, the first interlayer insulating layer 107, the first semiconductor layer A1, the third gate insulating layer 109, the second interlayer insulating layer 111, the first gate electrode G1, the second connection electrode 1720, the third connection electrode 1730, and the first organic insulating layer 113. The layers arranged on the first organic insulating layer 113 as illustrated in FIG. 10 may be arranged on the first organic insulating layer 113 in FIG. 15A.

The unevenness layer FA-L may be arranged on the second gate insulating layer 105. The unevenness layer FA-L may include the base unevenness FA-L1. A second additional inorganic insulating layer 106 may be arranged on the unevenness layer FA-L, and the second additional inorganic insulating layer 106 may completely shield the unevenness layer FA-L. The second additional inorganic insulating layer 106 may include a ninth unevenness 106-1 arranged in a portion corresponding to the base unevenness FA-L1. The second additional inorganic insulating layer 106 may include a material identical to or similar to the second gate insulating layer 105. The unevenness layer FA-L is the same or similar to that described with reference to FIGS. 12A and 12B, and thus a detailed description will be omitted.

In the case described above, the second storage electrode CEs2, the first interlayer insulating layer 107, and the first semiconductor layer A1 disposed on the second additional inorganic insulating layer 106 may include the fifth unevenness CEs2-1, the sixth unevenness 107-1, and the seventh unevenness A1-1, respectively.

Referring to FIG. 15B, the unevenness layer FA-L may be directly connected to the first semiconductor layer A1. The unevenness layer FA-L and the first semiconductor layer A1 may be connected to each other through the first contact hole CNT-1. Additionally, the second storage electrode CEs2 may have a structure that does not overlap the first contact hole CNT-1 in a plan view, as described with reference to FIG. 12B. The second storage electrode CEs2 may have a second hole with the first contact hole CNT-1 arranged thereinside.

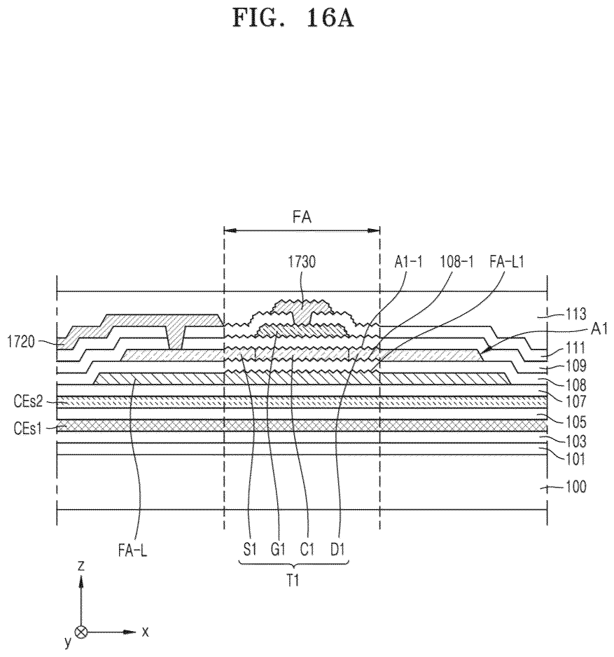

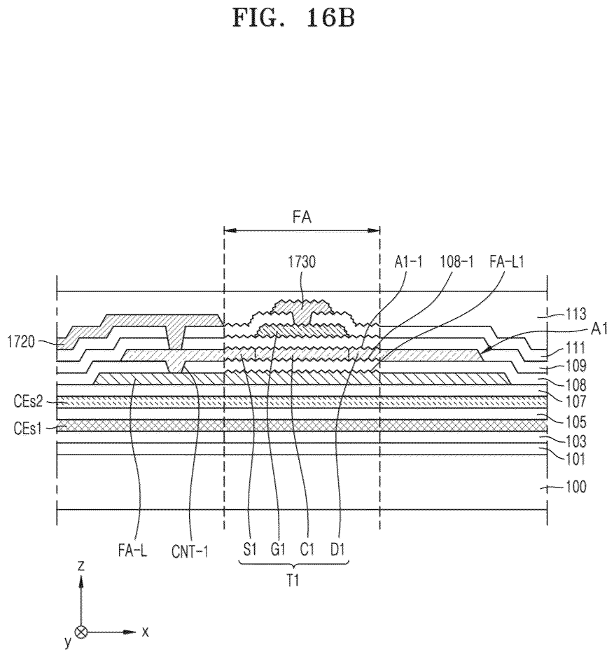

FIG. 16A is a cross-sectional view schematically illustrating a portion of a display area of a display panel, according to one or more embodiments. FIG. 16B is a cross-sectional view schematically illustrating a portion of a display area of a display panel, according to one or more embodiments. FIGS. 16A and 16B are schematic diagrams of a portion of a display panel corresponding to region F of FIG. 10, which may have a structure identical to or similar to the structure illustrated in FIG. 10. Below, description will focus on differences from the structure illustrated in FIG. 10.

Referring to FIG. 16A, the display panel may include the unevenness layer FA-L, the buffer layer 101, the first gate insulating layer 103, the first storage electrode CEs1, the second gate insulating layer 105, the second storage electrode CEs2, the first interlayer insulating layer 107, the first semiconductor layer A1, the third gate insulating layer 109, the second interlayer insulating layer 111, the first gate electrode G1, the second connection electrode 1720, the third connection electrode 1730, and the first organic insulating layer 113. The layers arranged on the first organic insulating layer 113 as illustrated in FIG. 10 may be arranged on the first organic insulating layer 113 in FIG. 16A.

The unevenness layer FA-L may be arranged on the first interlayer insulating layer 107. The unevenness layer FA-L may include the base unevenness FA-L1. A third additional inorganic insulating layer 108 may be arranged on the unevenness layer FA-L, and the third additional inorganic insulating layer 108 may completely shield the unevenness layer FA-L. The third additional inorganic insulating layer 108 may include a tenth unevenness 108-1 arranged in a portion corresponding to the base unevenness FA-L1. The third additional inorganic insulating layer 108 may include a material identical to or similar to the first interlayer insulating layer 107. The unevenness layer FA-L is the same or similar to that described with reference to FIGS. 12A and 12B, and thus a detailed description will be omitted.

In the case described above, the first semiconductor layer A1 disposed on the third additional inorganic insulating layer 108 may include the seventh unevenness A1-1.

Referring to FIG. 16B, the unevenness layer FA-L may be directly connected to the first semiconductor layer A1. The unevenness layer FA-L and the first semiconductor layer A1 may be connected to each other through the first contact hole CNT-1.

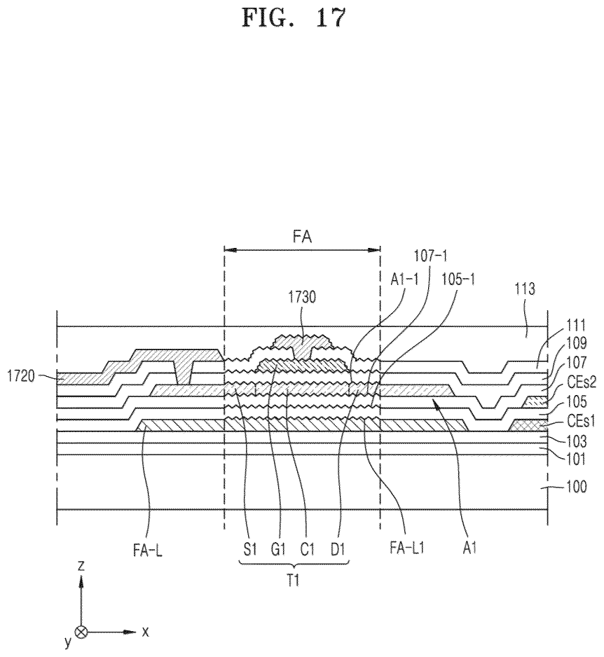

FIG. 17 is a cross-sectional view schematically illustrating a portion of a display area of a display panel according to one or more embodiments. FIG. 17 is a drawing schematically illustrating a portion of a display panel corresponding to region F of FIG. 10, and may have a structure identical or similar to the structure illustrated in FIG. 10. Below, description will focus on differences from the structure illustrated in FIG. 10.

Referring to FIG. 17, the display panel may include the unevenness layer FA-L, the buffer layer 101, the first gate insulating layer 103, the first storage electrode CEs1, the second gate insulating layer 105, the second storage electrode CEs2, the first interlayer insulating layer 107, the first semiconductor layer A1, the third gate insulating layer 109, the second interlayer insulating layer 111, the first gate electrode G1, the second connection electrode 1720, the third connection electrode 1730, and the first organic insulating layer 113. The layers arranged on the first organic insulating layer 113 as illustrated in FIG. 10 may be arranged on the first organic insulating layer 113 in FIG. 17.

The unevenness layer FA-L may be arranged on the first gate insulating layer 103. The unevenness layer FA-L may include the base unevenness FA-L1. The unevenness layer FA-L may be arranged on a same layer as the first storage electrode CEs1. In this case, the unevenness layer FA-L and the first storage electrode CEs1 may include a same material or different materials as described with reference to FIG. 12A.

The second gate insulating layer 105 may be arranged on the unevenness layer FA-L and the first storage electrode CEs1, and the second gate insulating layer 105 may completely shield the unevenness layer FA-L. The unevenness layer FA-L is the same or similar to that described with reference to FIGS. 12A and 12B, and thus a detailed description will be omitted.

In the above case, the second gate insulating layer 105, the first interlayer insulating layer 107, and the first semiconductor layer A1 disposed on the unevenness layer FA-L may include the fourth unevenness 105-1, the sixth unevenness 107-1, and the seventh unevenness A1-1.

The unevenness layer FA-L may be directly connected to the first semiconductor layer A1. The source region S1 of the unevenness layer FA-L and the first semiconductor layer A1 may be connected to each other through the first contact hole CNT-1, similarly to that illustrated in FIG. 16B. The first contact hole CNT-1 may pass through the second gate insulating layer 105 and the first interlayer insulating layer 107. Additionally, the first storage electrode CEs1 and the second storage electrode CEs2 may have a structure that does not overlap the first contact hole CNT-1.

The unevenness layer FA-L and the first storage electrode CEs1 may also be arranged in different layers. For example, the unevenness layer FA-L and the first storage electrode CEs1 may be arranged not to overlap each other, and the unevenness layer FA-L may be arranged on the first gate insulating layer 103, as illustrated in FIG. 14A, and the first additional inorganic insulating layer 104 may be arranged on the unevenness layer FA-L, the first storage electrode CEs1 may be arranged on the first additional inorganic insulating layer 104, and the second gate insulating layer 105 may be arranged on the first storage electrode CEs1. In this case, in the unevenness area FA, each of the first additional inorganic insulating layer 104, the second gate insulating layer 105, the third gate insulating layer 109, and the first semiconductor layer A1 may have an unevenness.

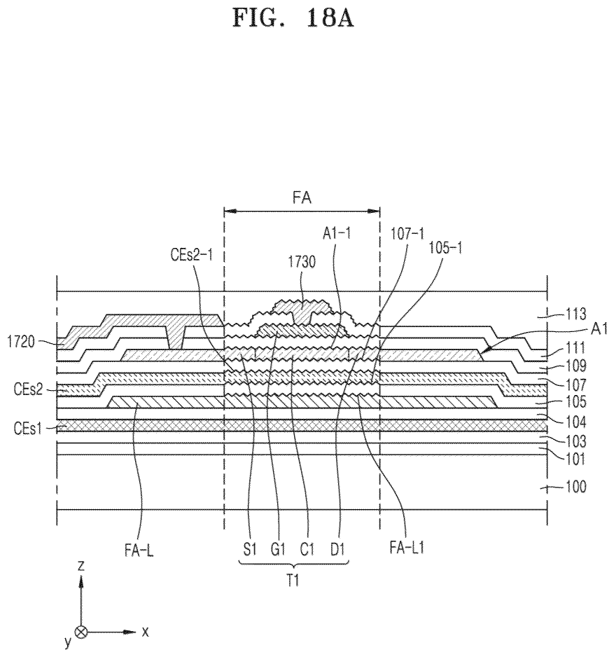

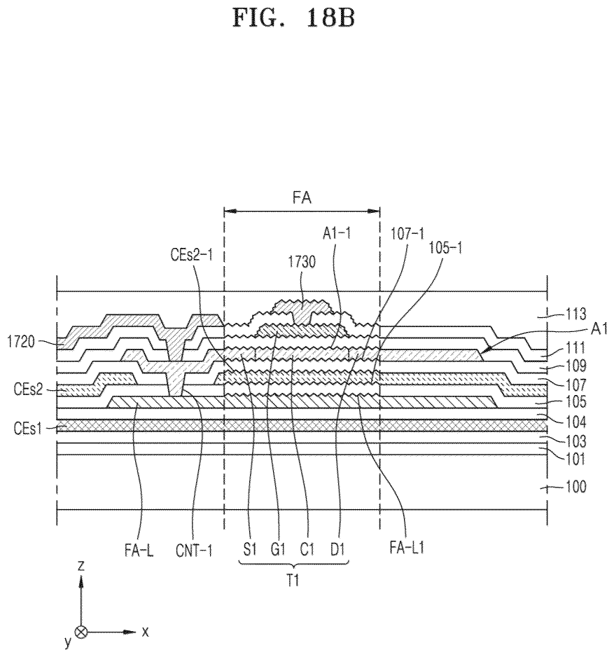

FIG. 18A is a cross-sectional view schematically illustrating a portion of a display area of a display panel, according to one or more embodiments. FIG. 18B is a cross-sectional view schematically illustrating a portion of a display area of a display panel, according to one or more embodiments. FIGS. 18A and 18B are schematic diagrams illustrating a portion of a display panel corresponding to region F of FIG. 10, which may have a structure identical to or similar to the structure illustrated in FIG. 10. Below, description will focus on differences from the structure illustrated in FIG. 10.

Referring to FIG. 18A, the display panel may include the unevenness layer FA-L, the buffer layer 101, the first gate insulating layer 103, the first storage electrode CEs1, the second gate insulating layer 105, the second storage electrode CEs2, the first interlayer insulating layer 107, the first semiconductor layer A1, the third gate insulating layer 109, the second interlayer insulating layer 111, the first gate electrode G1, the second connection electrode 1720, the third connection electrode 1730, and the first organic insulating layer 113. The layers arranged on the first organic insulating layer 113 as illustrated in FIG. 10 may be arranged on the first organic insulating layer 113 in FIG. 18A.

The unevenness layer FA-L may be arranged on the first additional inorganic insulating layer 104. The first additional inorganic insulating layer 104 may shield the first storage electrode CEs1 and separate the unevenness layer FA-L and the first storage electrode CEs1 from each other. The unevenness layer FA-L may include the base unevenness FA-L1.

The second gate insulating layer 105 may be arranged on the unevenness layer FA-L, and the second gate insulating layer 105 may completely shield the unevenness layer FA-L. The unevenness layer FA-L is the same or similar to that described with reference to FIGS. 12A and 12B, and thus a detailed description will be omitted.

In the case described above, each of the second gate insulating layer 105, the second storage electrode CEs2, the first interlayer insulating layer 107, and the first semiconductor layer A1 sequentially arranged on the unevenness layer FA-L may have the fourth unevenness 105-1, the fifth unevenness CEs2-1, the sixth unevenness 107-1, and the seventh unevenness A1-1, respectively.

Referring to FIG. 18B, the unevenness layer FA-L may be directly connected to the first semiconductor layer A1. The unevenness layer FA-L and the first semiconductor layer A1 may be connected to each other through the first contact hole CNT-1. Additionally, the second storage electrode CEs2 may have a structure that does not overlap the first contact hole CNT-1 in a plan view. The second storage electrode CEs2 may include a second hole, and the first contact hole CNT-1 may be arranged inside the second hole.

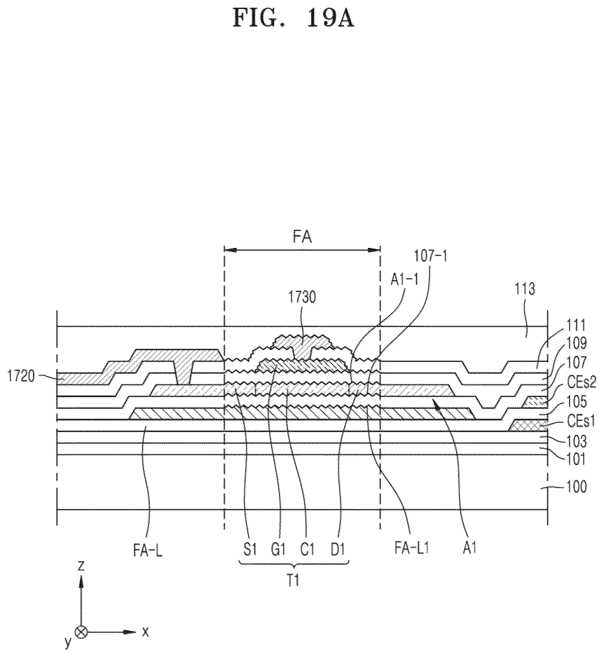

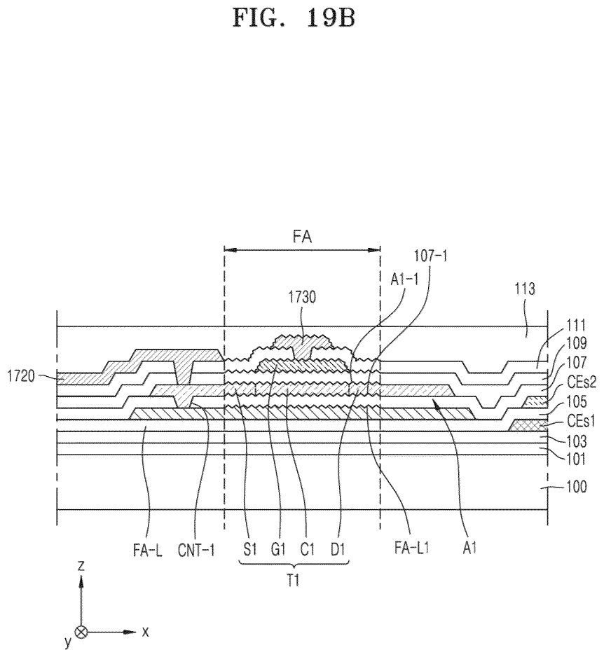

FIG. 19A is a cross-sectional view schematically illustrating a portion of a display area of a display panel, according to one or more embodiments. FIG. 19B is a cross-sectional view schematically illustrating a portion of a display area of a display panel, according to one or more embodiments. FIGS. 19A and 19B are schematic diagrams of a portion of a display panel corresponding to region F of FIG. 10, which may have a structure identical to or similar to the structure illustrated in FIG. 10. Below, description will focus on differences from the structure illustrated in FIG. 10.

Referring to FIG. 19A, the display panel may include the unevenness layer FA-L, the buffer layer 101, the first gate insulating layer 103, the first storage electrode CEs1, the second gate insulating layer 105, the second storage electrode CEs2, the first interlayer insulating layer 107, the first semiconductor layer A1, the third gate insulating layer 109, the second interlayer insulating layer 111, the first gate electrode G1, the second connection electrode 1720, the third connection electrode 1730, and the first organic insulating layer 113. The layers arranged on the first organic insulating layer 113 as illustrated in FIG. 10 may be arranged on the first organic insulating layer 113 in FIG. 19A.

The unevenness layer FA-L may be arranged on the second gate insulating layer 105. The unevenness layer FA-L may include the base unevenness FA-L1. The unevenness layer FA-L may be arranged on a same layer as the second storage electrode CEs2. In this case, the unevenness layer FA-L and the second storage electrode CEs2 may include a same material or different materials. If the unevenness layer FA-L includes a different material from that of the second storage electrode CEs2, the unevenness layer FA-L may include polysilicon.

The first interlayer insulating layer 107 may be arranged on the unevenness layer FA-L and the second storage electrode CEs2, and the first interlayer insulating layer 107 may completely shield the unevenness layer FA-L. The unevenness layer FA-L is the same or similar to that described with reference to FIGS. 12A and 12B, and thus a detailed description will be omitted.

In the above case, the first interlayer insulating layer 107 and the first semiconductor layer A1 disposed on the unevenness layer FA-L may include the sixth unevenness 107-1 and the seventh unevenness A1-1, respectively.

Referring to FIG. 19B, the unevenness layer FA-L may be directly connected to the first semiconductor layer A1. The unevenness layer FA-L and the first semiconductor layer A1 may be connected to each other through the first contact hole CNT-1 arranged in the third gate insulating layer 109. Additionally, the first storage electrode CEs1 and the second storage electrode CEs2 may have a structure that does not overlap the first contact hole CNT-1 in plan view.

The unevenness layer FA-L and the second storage electrode CEs2 may be arranged in different layers without overlapping each other. For example, the unevenness layer FA-L and the second storage electrode CEs2 may be arranged so as not to overlap each other, and the unevenness layer FA-L may be arranged on the second gate insulating layer 105, the second additional inorganic insulating layer 106 may be arranged on the unevenness layer FA-L, the first storage electrode CEs1 may be arranged on the second additional inorganic insulating layer, and the first interlayer insulating layer 107 may be arranged on the first storage electrode CEs1. In this case, a portion of each of the second additional inorganic insulating layer 106, the first interlayer insulating layer 107 and the first semiconductor layer A1 arranged in the unevenness area FA may have an unevenness. In another embodiment, the second storage electrode CEs2 may be disposed on the second gate insulating layer 105, the second additional inorganic insulating layer 106 may be disposed on the second storage electrode CEs2, and the unevenness layer FA-L may be disposed on the second additional inorganic insulating layer 106. The first interlayer insulating layer 107 and the first semiconductor layer A1 may be sequentially arranged on the unevenness layer FA-L in a structure having unevenness.

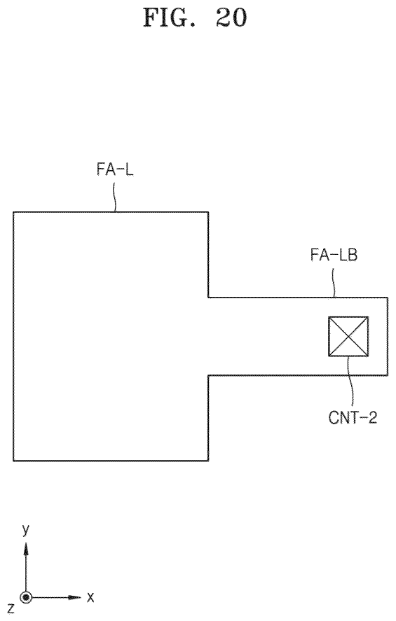

FIG. 20 is a plan view schematically illustrating an unevenness layer arranged in a display area of a display panel, according to one or more embodiments.

Referring to FIG. 20, the unevenness layer FA-L may be connected to a bridge layer FA-LB for connecting to the source region S1 of the first semiconductor layer A1 and a second connection electrode. In the bridge layer FA-LB, the first semiconductor layer A1 may protrude from the unevenness layer FA-L to the source region S1.

The bridge layer FA-LB may be connected to the second connection electrode 1720 through the second contact hole CNT-2. The unevenness layer FA-L may correspond to the unevenness area FA described above. An upper surface of the bridge layer FA-LB may have an unevenness similar to that of the unevenness layer FA-L, or may be flat and have no unevenness, unlike the unevenness layer FA-L. For convenience of description, description will further focus on the bridge layer FA-LB that has no unevenness, unlike the unevenness layer FA-L.

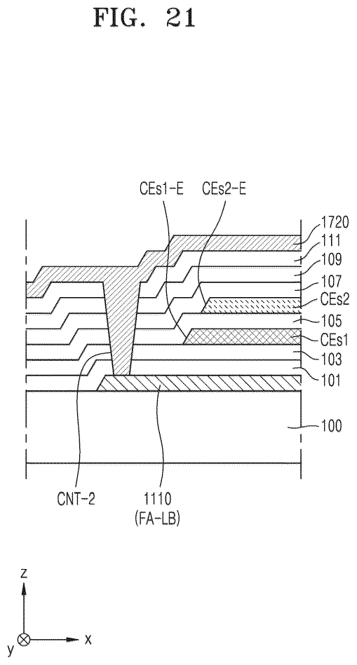

FIGS. 21 to 28 are cross-sectional views schematically illustrating a portion of a display area of a display panel according to one or more embodiments. FIGS. 21 to 28 are cross-sectional views schematically illustrating an area corresponding to a bridge layer of an unevenness layer. A portion where a first semiconductor layer is arranged may have the shape illustrated in FIGS. 12A to 19B.

Referring to FIG. 21, the bridge layer FA-LB may extend in one direction from the unevenness layer FA-L. The bridge layer FA-LB may protrude further in one direction than a first end CEs1-E of the first storage electrode CEs1 and a second end CEs2-E of the second storage electrode CEs2. Accordingly, the bridge layer FA-LB may be connected to a source region of the first semiconductor layer without interference by the first storage electrode CEs1 and the second storage electrode CEs2. The bridge layer FA-LB may be arranged on the substrate 100 as illustrated in FIG. 21.

The buffer layer 101, the first gate insulating layer 103, the second gate insulating layer 105, the first interlayer insulating layer 107, the third gate insulating layer 109, the second interlayer insulating layer 111, and the second connection electrode 1720 may be sequentially arranged on a portion of the bridge layer FA-LB, which corresponds to the second contact hole CNT-2. The second contact hole CNT-2 may pass through the buffer layer 101, the first gate insulating layer 103, the second gate insulating layer 105, the first interlayer insulating layer 107, the third gate insulating layer 109, and the second interlayer insulating layer 111, and the second connection electrode 1720 and the bridge layer FA-LB may be connected to each other through the second contact hole CNT-2.

In the above case, a main portion of the unevenness layer FA-L may have the shape as illustrated in FIG. 12A or FIG. 12B.

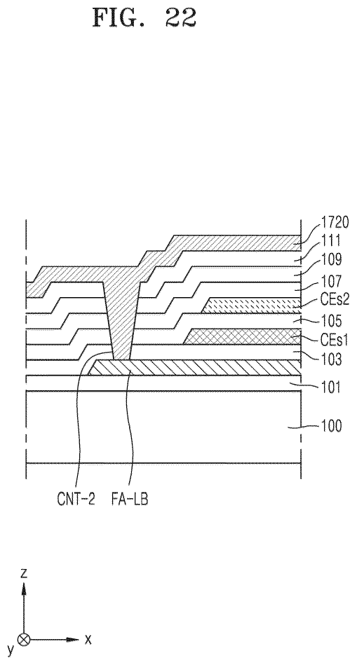

Referring to FIG. 22, the bridge layer FA-LB may be arranged on the buffer layer 101. The first gate insulating layer 103, the second gate insulating layer 105, the first interlayer insulating layer 107, the third gate insulating layer 109, the second interlayer insulating layer 111, and the second connection electrode 1720 may be sequentially arranged on a portion of the bridge layer FA-LB, which corresponds to the second contact hole CNT-2. The second contact hole CNT-2 may pass through the first gate insulating layer 103, the second gate insulating layer 105, the first interlayer insulating layer 107, the third gate insulating layer 109, and the second interlayer insulating layer 111, and the second connection electrode 1720 and the bridge layer FA-LB may be connected to each other through the second contact hole CNT-2.

In the above case, the main portion of the unevenness layer FA-L may have the shape as illustrated in FIG. 13A or FIG. 13B.

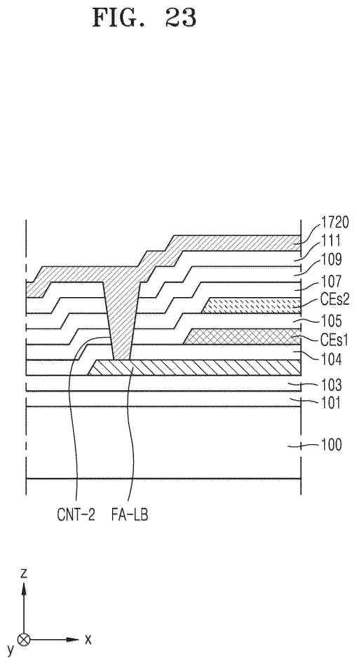

Referring to FIG. 23, the bridge layer FA-LB may be arranged on the first gate insulating layer 103. The first additional inorganic insulating layer 104, the second gate insulating layer 105, the first interlayer insulating layer 107, the third gate insulating layer 109, the second interlayer insulating layer 111, and the second connection electrode 1720 may be sequentially arranged on a portion of the bridge layer FA-LB, which corresponds to the second contact hole CNT-2. The second contact hole CNT-2 may pass through the first additional inorganic insulating layer 104, the second gate insulating layer 105, the first interlayer insulating layer 107, the third gate insulating layer 109, and the second interlayer insulating layer 111, and the second connection electrode 1720 and the bridge layer FA-LB may be connected to each other through the second contact hole CNT-2.

In the above case, the main portion of the unevenness layer FA-L may have the shape as illustrated in FIG. 14A or FIG. 14B.

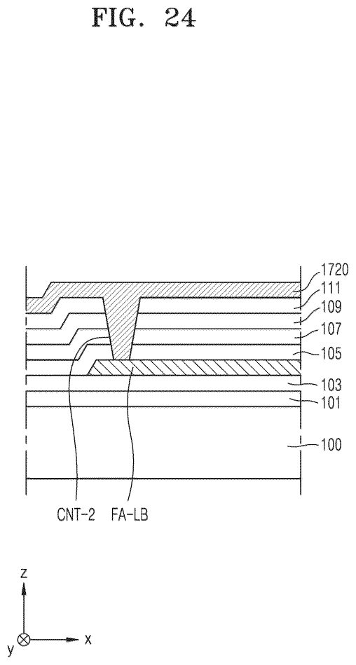

Referring to FIG. 24, the bridge layer FA-LB may be arranged on the first gate insulating layer 103. The second gate insulating layer 105, the first interlayer insulating layer 107, the third gate insulating layer 109, the second interlayer insulating layer 111, and the second connection electrode 1720 may be sequentially arranged on a portion of the bridge layer FA-LB, which corresponds to the second contact hole CNT-2. The second contact hole CNT-2 may pass through the second gate insulating layer 105, the first interlayer insulating layer 107, the third gate insulating layer 109, and the second interlayer insulating layer 111, and the second connection electrode 1720 and the bridge layer FA-LB may be connected to each other through the second contact hole CNT-2.

In the above case, the main portion of the unevenness layer FA-L may have the shape as illustrated in FIG. 17.

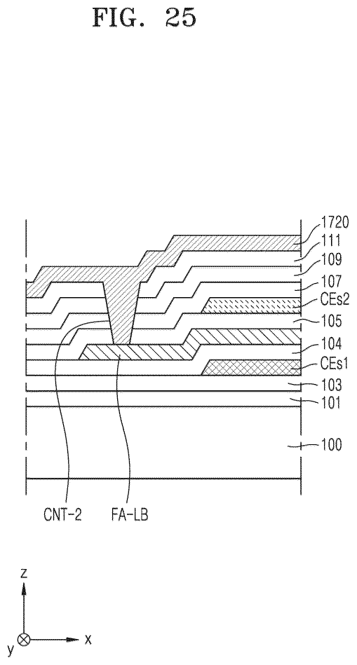

Referring to FIG. 25, the bridge layer FA-LB may be arranged on the first additional inorganic insulating layer 104. The second gate insulating layer 105, the first interlayer insulating layer 107, the third gate insulating layer 109, the second interlayer insulating layer 111, and the second connection electrode 1720 may be sequentially arranged on a portion of the bridge layer FA-LB, which corresponds to the second contact hole CNT-2. The second contact hole CNT-2 may pass through the second gate insulating layer 105, the first interlayer insulating layer 107, the third gate insulating layer 109, and the second interlayer insulating layer 111, and the second connection electrode 1720 and the bridge layer FA-LB may be connected to each other through the second contact hole CNT-2.

In the above case, the bridge layer FA-LB may further protrude than an end of the first storage electrode CEs1 and an end of the second storage electrode CEs2.

In the above case, the main portion of the unevenness layer FA-L may have the shape as illustrated in FIG. 18A or FIG. 18B.

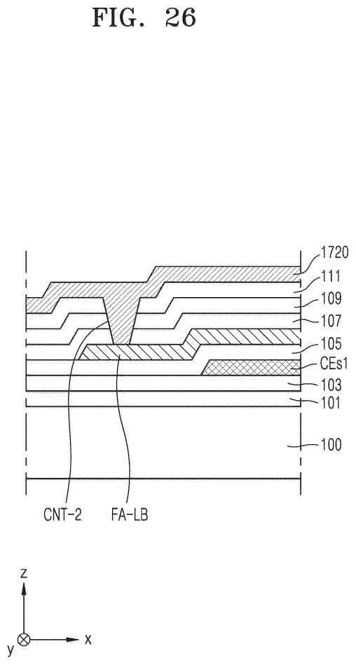

Referring to FIG. 26, the bridge layer FA-LB may be arranged on the second gate insulating layer 105. The first interlayer insulating layer 107, the third gate insulating layer 109, the second interlayer insulating layer 111, and the second connection electrode 1720 may be sequentially arranged on a portion of the bridge layer FA-LB, which corresponds to the second contact hole CNT-2. The second contact hole CNT-2 may pass through the first interlayer insulating layer 107, the third gate insulating layer 109, and the second interlayer insulating layer 111, and the second connection electrode 1720 and the bridge layer FA-LB may be connected to each other through the second contact hole CNT-2. The bridge layer FA-LB may protrude further than the end of the first storage electrode CEs1.

In the above case, the main portion of the unevenness layer FA-L may have the shape as illustrated in FIG. 19A or FIG. 19B.

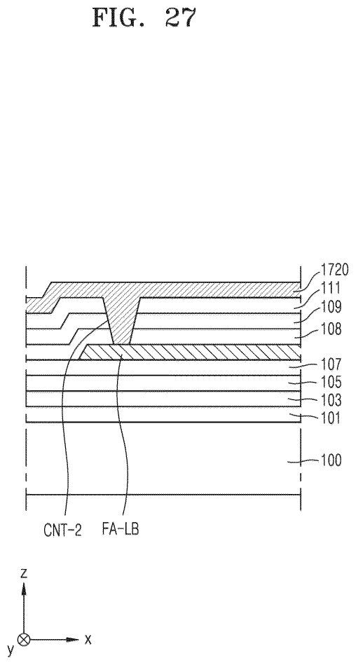

Referring to FIG. 27, the bridge layer FA-LB may be arranged on the second gate insulating layer 105. The third additional inorganic insulating layer 108, the third gate insulating layer 109, the second interlayer insulating layer 111, and the second connection electrode 1720 may be sequentially arranged on a portion of the bridge layer FA-LB, which corresponds to the second contact hole CNT-2. The second contact hole CNT-2 may pass through the third additional inorganic insulating layer 108, the third gate insulating layer 109, and the second interlayer insulating layer 111, and the second connection electrode 1720 and the bridge layer FA-LB may be connected to each other through the second contact hole CNT-2.

In the above case, the main portion of the unevenness layer FA-L may have the shape as illustrated in FIG. 15A or FIG. 15B.

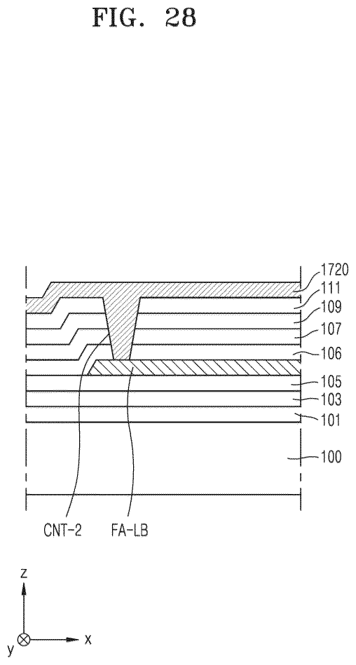

Referring to FIG. 28, the bridge layer FA-LB may be arranged on the second gate insulating layer 105. The second additional inorganic insulating layer 106, the first interlayer insulating layer 107, the third gate insulating layer 109, the second interlayer insulating layer 111, and the second connection electrode 1720 may be sequentially arranged on a portion of the bridge layer FA-LB, which corresponds to the second contact hole CNT-2. The second contact hole CNT-2 may pass through the second additional inorganic insulating layer 106, the first interlayer insulating layer 107, the third gate insulating layer 109, and the second interlayer insulating layer 111, and the second connection electrode 1720 and the bridge layer FA-LB may be connected to each other through the second contact hole CNT-2.

In the above case, the main portion of the unevenness layer FA-L may have the shape as illustrated in FIG. 16A or 16B.

According to the display panel and the electronic device according to embodiments, brightness may be precisely controlled in a low-brightness range.

According to the display panel and the electronic device according to embodiments, a clear image may be provided while precisely controlling the brightness of each pixel.

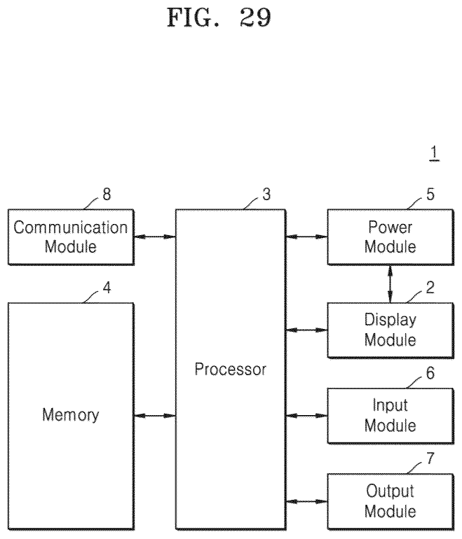

FIG. 29 is a block diagram of an electronic device 1 according to one or more embodiments.

Referring to FIG. 29, the electronic device 1 according to one or more embodiments may include a display module 2 including a display panel, a processor 3, a memory 4, and a power module 5.

The processor 3 may include at least one of a central processing unit (CPU), an application processor (AP), a graphics processing unit (GPU), a communication processor (CP), an image signal processor (ISP), and a controller. according to one or more embodiments, the processor 3 may be provided by being divided into two or more processors in a functional or structural perspective. For example, the processor 3 may include a main processor as a first driving chip including a CPU and an auxiliary processor as a second driving chip including a controller configured to receive an image signal from the main processor and process the image signal according to the interface specifications of the display module 2.

The memory 4 may include at least one of a non-volatile memory and a volatile memory. The memory 4 may store data information necessary for operations of the processor 3 or the display module 2. When the processor 3 executes an application stored in the memory 4e, an image data signal and/or an input control signal may be transmitted to the display module 2, and the display module 2 may be configured to process the received signal and output image information through a display screen.

The power module 5 may include a power supply module, such as a power adaptor or a battery device, and a power conversion module configured to convert a power supply from the power supply module and generate power necessary for operations of the electronic device 1. The power conversion by the power conversion module may include direct current (DC)-DC conversion, alternating current (AC)-DC conversion, and DC-AC conversion, but is not limited thereto.

The electronic device 1 may further include an input module 6, a non-image output module 7, and/or a communication module 8.

The input module 6 may provide input information to the processor 3 and/or the display module 2. The input module 6 may include not only a physical button, a keyboard, and a microphone, but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors, such as a blood-pressure sensor, a blood-sugar sensor, an electrocardiogram sensor, a heart rate sensor, etc.

The non-image output module 7 may receive information except for an image from the processor 3 and provide the information to a user. Examples of the non-image output module 7 may include a sound module, a haptic module, a light-emission module, etc. and may also include other functionally intrinsic modules (for example, a cooling module of a refrigerator, etc.) of an electronic device.

The communication module 8 may be configured to perform transmission and reception of information between the electronic device 1 and an external device and may include a receiver and a transmitter. The communication module 8 may include various wireless communication modules, such as a mobile communication module, a WiFi module, a Bluetooth module, etc., or various wired communication modules.

At least of the components of the electronic device 1 described above may be included in the display panel 10 according to the embodiments described above. Also, some of separate modules functionally included in one module may be included in the electronic device 1 and the others may be provided separately from the electronic device 1. For example, the electronic device 1 may include the display module 2, and the processor 3, the memory 4, and the power module 5 may be provided in the electronic device 1, rather than the electronic device 1, as other devices. As another example, the power module 5 may be provided in the electronic device 1 and may provide a power supply to the processor 3 and the memory 4 which are provided in the electronic device 1, rather than the electronic device 1. However, the disclosure is not limited thereto.

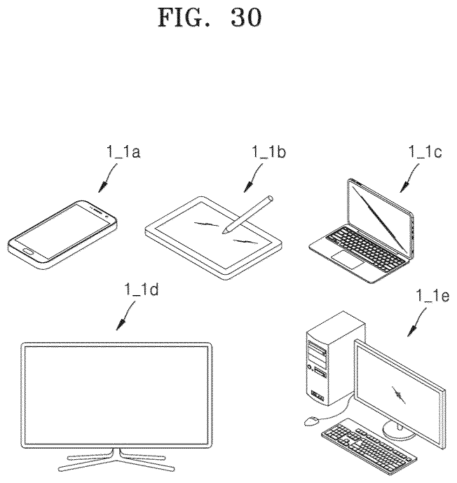

FIGS. 30 to 32 are schematic views of electronic devices according to various embodiments. FIGS. 30 to 32 illustrate examples of various electronic devices in which the display panel 10 according to embodiments is included.

FIG. 30 illustrates a smartphone 1_1a, a tablet PC 1_1b, a laptop computer 1_1c, a TV 1_1d, and a monitor 1_1e for a desk, as examples of the electronic devices.

The smartphone 1_1a may include an input module, such as a touch sensor, etc., and a communication module, in addition to the display module 2. The smartphone 1_1a may process information received through the communication module or other input modules and display the processed information through a display module of the electronic device 1. The tablet PC 1_1b, the laptop computer 1_1c, the TV 1_1d, and the monitor 1_1e for a desk may also include a display module and an input module, similarly as the smartphone 1_1a, and may further include a communication module according to cases.

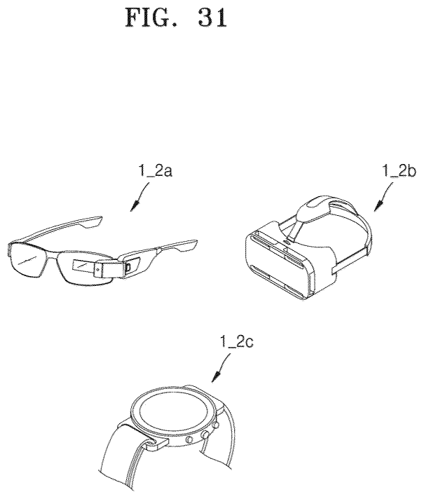

FIG. 31 illustrates a case where the electronic device 1 including the display module 2 includes a wearable electronic device. The wearable electronic device may include smart glasses 1_2a, an HMD 1_2b or a smart watch 1_2c, etc.

The smart glasses 1_2a and the HMD 1_2b may include a display module configured to project a display image and a reflector configured to reflect the projected display screen and provide the display screen to a user's eye, so as to provide a screen of virtual reality (VR) or augmented reality (AR) to the user.

The smart watch 1_2c may include a biometric sensor as an input device and may provide biometric information recognized through the biometric sensor to the user through a display module.

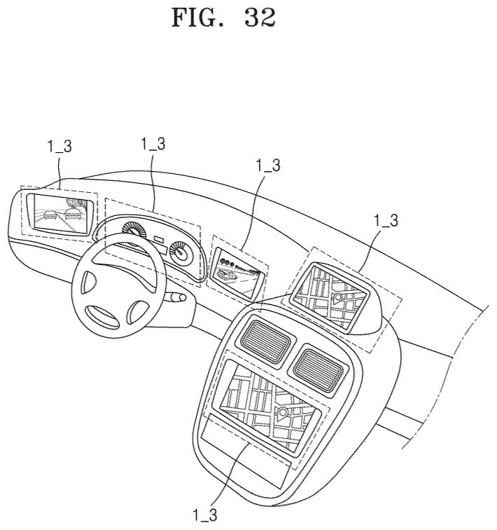

FIG. 32 illustrates a case where the electronic device 1 including the display module 2 includes a vehicle. For example, an electronic device 1_3 may be used in a gauge or a center fascia of the vehicle, or may be used as a central information display (CID) arranged on a dashboard of the vehicle, or a room mirror display substituting a side-view mirror.

The electronic device in which the display panel 10 according to embodiments is included, may include not only devices mainly including a screen display, such as an advertisement board, an electronic display board, a game machine, etc., but also various home appliances for displaying information through a display module, such as a refrigerator, a laundry machine, a dryer, an air conditioner, a robot cleaner, etc. Also, when the display module has a light-transmission function, the electronic device may include a smart window or a transparent display panel for displaying the background and a display image together. Types of the electronic device according to one or more embodiments are not limited to the examples described above, and various other electronic devices may also be provided.

In an embodiment, a display panel may include: a substrate; an unevenness layer on the substrate; and a transistor including a gate electrode and a semiconductor layer on the unevenness layer, wherein at least one of a surface of the unevenness layer or a surface of the semiconductor layer have unevenness.

The display panel may further include a light-emitting diode, wherein the transistor may include a driving transistor configured to drive the light-emitting diode.

An uneven portion of the surface of the semiconductor layer may overlap the gate electrode in a plan view of the display panel.

The semiconductor layer may include a first surface facing the gate electrode and a second surface opposite the first surface. The first surface and the second surface may have irregular topologies.

The unevenness layer may be connected to a source region of the semiconductor layer.

The unevenness layer may be directly connected to the source region of the semiconductor layer.

In a plan view, a channel region of the semiconductor layer may be aligned with an uneven region of the unevenness layer.

The unevenness layer may include polysilicon.

The semiconductor layer may include an oxide semiconductor layer.

The unevenness layer may include an inorganic insulating layer between the substrate and the semiconductor layer.

An electronic device may include the display panel and a lower cover forming an outer appearance of the display panel and having an opening exposing a portion of the display panel.

In another embodiment, an electronic device may include: a display panel including: a light-emitting diode; a field-effect transistor configured to drive the light-emitting diode and including: a source electrode, a drain electrode, and a gate electrode; a polysilicon layer below the source electrode, the drain electrode, and the gate electrode, the polysilicon layer being directly connected to the source electrode; an oxide semiconductor layer between the source electrode and the polysilicon layer, the oxide semiconductor layer contacting the source electrode and the polysilicon layer; and a processor configured to control the display panel to display an image, wherein at least one of a surface of the polysilicon layer or a surface of the oxide semiconductor layer includes unevenness.

The surface of the polysilicon layer may include an even portion and an uneven portion, and the unevenness of the polysilicon layer is presented only in the uneven portion of the polysilicon layer that overlaps the gate electrode in a plain view of the display panel.

The oxide semiconductor layer may a first surface facing the gate electrode and a second surface opposite the first surface, and the first surface and the second surface have irregular topologies.

The polysilicon layer is connected to the source electrode through a contact hole that vertically extends from the source electrode to the polysilicon layer.

A conductive material filled within the contact hole increases a subthreshold slope of the field-effect transistor.

The polysilicon layer is directly connected to the source electrode.

In a plan view of the display panel, a channel region of the field-effect transistor is aligned with an uneven region of the polysilicon layer.

The polysilicon layer may include an even region that does not overlap the channel region of the field-effect transistor in a plan view of the display panel.

The polysilicon layer may include an inorganic insulating layer between a substrate of the display panel and the oxide semiconductor layer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate;
an unevenness layer on the substrate; and
a transistor comprising a gate electrode and a semiconductor layer on the unevenness layer,
wherein at least one of a surface of the unevenness layer or a surface of the semiconductor layer comprises unevenness.

2. The display panel of claim 1, further comprising a light-emitting diode,
wherein the transistor comprises a driving transistor configured to drive the light-emitting diode.

3. The display panel of claim 1, wherein an uneven portion of the surface of the semiconductor layer overlaps the gate electrode in a plan view of the display panel.

4. The display panel of claim 1, wherein the semiconductor layer comprises a first surface facing the gate electrode and a second surface opposite the first surface, and
wherein the first surface and the second surface have irregular topologies.

5. The display panel of claim 1, wherein the unevenness layer is connected to a source region of the semiconductor layer.

6. The display panel of claim 5, wherein the unevenness layer is directly connected to the source region of the semiconductor layer.

7. The display panel of claim 1, wherein, in a plan view, a channel region of the semiconductor layer is aligned with an uneven region of the unevenness layer.

8. The display panel of claim 1, wherein the unevenness layer comprises polysilicon.

9. The display panel of claim 1, wherein the semiconductor layer comprises an oxide semiconductor layer.

10. The display panel of claim 1, wherein the unevenness layer comprises an inorganic insulating layer between the substrate and the semiconductor layer.

11. An electronic device comprising:
a display panel; and
a processor configured to control the display panel to display an image,
wherein the display panel comprises:
a substrate;
an unevenness layer on the substrate; and
a transistor comprising a gate electrode and a semiconductor layer on the unevenness layer,
wherein at least one of a surface of the unevenness layer or a surface of the semiconductor layer comprises unevenness.

12. The electronic device of claim 11, wherein the display panel further comprises a light-emitting diode,
wherein the transistor comprises a driving transistor configured to drive the light-emitting diode.

13. The electronic device of claim 11, wherein an uneven portion of the surface of the semiconductor layer overlaps the gate electrode in a plan view of the display panel.

14. The electronic device of claim 11, wherein the semiconductor layer comprises a first surface facing the gate electrode and a second surface opposite the first surface, and
wherein the first surface and the second surface have a irregular topologies.

15. The electronic device of claim 11, wherein the unevenness layer is connected to a source region of the semiconductor layer.

16. The electronic device of claim 15, wherein the unevenness layer is directly connected to the source region of the semiconductor layer.

17. The electronic device of claim 11, wherein, in a plan view, a channel region of the semiconductor layer is aligned with an uneven region of the unevenness layer.

18. The electronic device of claim 11, wherein the unevenness layer comprises polysilicon.

19. The electronic device of claim 11, wherein the semiconductor layer comprises an oxide semiconductor layer.

20. The electronic device of claim 11, wherein the unevenness layer comprises an inorganic insulating layer between the substrate and the semiconductor layer.
